(19) United States
(12) Patent Application Publication
(10) Pub. No.: US 2026/0045931 A1
(43) Pub. Date: Feb. 12, 2026

(54) ACOUSTIC BRAGG REFLECTOR IN A SOLIDLY-MOUNTED TRANSVERSELY-EXCITED BULK ACOUSTIC RESONATOR

(71) Applicant: Murata Manufacturing Co, Ltd., Nagaokakyo-shi (JP)

(72) Inventors: Drew MOROSIN, Oxnard, CA (US); Bryant GARCIA, Mississauga (CA); John P. KOULAKIS, Los Angeles, CA (US); Greg DYER, Santa Barbara, CA (US)

(21) Appl. No.: 19/289,413

(22) Filed: Aug. 4, 2025

Related U.S. Application Data
(60) Provisional application No. 63/679,812, filed on Aug. 6, 2024.

(51) Int. Cl. H03H 9/17; H03H 9/02

(52) U.S. Cl. CPC H03H 9/175; H03H 9/02228

(57) ABSTRACT

An acoustic resonator is provided that includes a piezoelectric layer, an interdigital transducer (IDT) including a plurality of interleaved fingers on the piezoelectric layer, a substrate, and an acoustic reflector between the piezoelectric layer and the substrate. The acoustic reflector that is on the piezoelectric layer includes alternating first layers of first materials and second layers of second materials. A first acoustic impedance of the first materials is different from a second acoustic impedance of the second materials. A ratio of a pitch of the IDT over a thickness of the piezoelectric layer is less than 10. A first thickness of at least one of the first layers is larger than a quarter of a first wavelength λ₁. λ₁ is an acoustic wavelength of a shear bulk wave in the at least one of the first layers at a resonance frequency of the transversely-excited bulk acoustic resonator.

### CROSS REFERENCE TO RELATED APPLICATIONS

This application claims priority to U.S. Patent Provisional No. 63/679,812, filed Aug. 6, 2024, the entire contents of which are hereby incorporated by reference.

### TECHNICAL FIELD

This disclosure relates to filters including transversely-excited film bulk acoustic resonators (XBARs).

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

However, in order to provide the type of high-level performance required by the above-described communications applications, potential loss mechanisms that detract from the performance of the RF filters may need to be addressed. One such loss mechanism is an insertion loss (IL).

### SUMMARY

Aspects of the disclosure includes a solidly-mounted transversely-excited bulk acoustic resonator (SM-XBAR). The SM-XBAR includes a piezoelectric layer, an interdigital transducer (IDT) including a plurality of interleaved fingers on the piezoelectric layer, a substrate, and an acoustic reflector between the piezoelectric layer and the substrate. The acoustic reflector includes alternating first layers of first materials and second layers of second materials. A first acoustic impedance of the first materials may be different from a second acoustic impedance of the second materials, the acoustic reflector being on the piezoelectric layer. A ratio of a pitch of the IDT over a thickness of the piezoelectric layer is less than 10, a first thickness of at least one of the first layers is larger than a wavelength λ₁, where λ₁ is the acoustic wavelength of shear bulk wave in specific layer at desired resonance frequency of SM-XBAR.

In an exemplary aspect of the acoustic resonator, the first thickness of the at least one first layer is between 0.26λ₁ to 0.32λ₁.

In an exemplary aspect of the acoustic resonator, a second thickness of the at least one second layer is larger than a quarter of a second wavelength λ₂, and λ₂ is an acoustic wavelength of the shear bulk wave in the at least one second layer.

In an exemplary aspect of the acoustic resonator, the second thickness of the at least one second layer is between 0.26λ₂ to 0.32λ₂.

In an exemplary aspect of the acoustic resonator, the first thickness of the at least one first layer is between 0.26λ₁ to 0.32λ₁.

In an exemplary aspect of the acoustic resonator, the first acoustic impedance of the first materials is larger than the second acoustic impedance of the second materials.

In an exemplary aspect of the acoustic resonator, the first thickness of the at least one first layer is less than 0.35λ₁.

In an exemplary aspect of the acoustic resonator, a second thickness of at least one second layer is between 0.21λ₂ to less than 0.25λ₂, and λ₂ is an acoustic wavelength of the shear bulk wave in the at least one second layer.

In an exemplary aspect of the acoustic resonator, the piezoelectric layer and the IDT are configured such that a radio frequency signal applied to the IDT excites a primary shear acoustic mode in the piezoelectric layer, such that an electric field is excited in a substantially lateral direction in the piezoelectric layer, and wave propagation of the primary shear acoustic mode is substantially perpendicular to the lateral direction of the electric field.

In an exemplary aspect of the acoustic resonator, the plurality of interleaved fingers includes first parallel fingers extending from a first busbar and second parallel fingers extending from a second busbar, the first and second parallel fingers are interleaved with each other, and the first busbar and the second busbar are disposed on the piezoelectric layer, and the IDT is on a surface of the piezoelectric layer and the thickness of the piezoelectric layer and the first thickness are measured in a direction orthogonal to the surface of the piezoelectric layer.

In an exemplary aspect of the acoustic resonator, a thickness of at least one additional layer of the first layers of the first materials is greater than 0.75λ₁ or a thickness of at least one additional layer of the second layers of second materials is greater than 0.75λ₂.

In an exemplary aspect of the acoustic resonator, the IDT and the acoustic reflector are on a same side of the piezoelectric layer.

In an exemplary aspect of the acoustic resonator, the IDT and the acoustic reflector are on different sides of the piezoelectric layer.

Aspects of the disclosure includes a bandpass filter. In an exemplary aspect, the bandpass filter includes a plurality of acoustic resonators comprising one or more series resonators and one or more shunt resonators, one of the plurality of acoustic resonators including a solidly-mounted transversely-excited bulk acoustic resonator (SM-XBAR) that includes a piezoelectric layer, an interdigital transducer (IDT) including a plurality of interleaved fingers on the piezoelectric layer, a substrate, and an acoustic reflector between the piezoelectric layer and the substrate, the acoustic reflector being on the piezoelectric layer, the acoustic reflector includes alternating first layers of first materials and second layers of second materials. Moreover, a first acoustic impedance of the first materials is different from a second acoustic impedance of the second materials, a ratio of a pitch of the IDT over a thickness of the piezoelectric layer is less than 10, a first thickness of at least one of the first layers is larger than a quarter of a first wavelength λ₁, and λ₁ is an acoustic wavelength of a shear bulk wave in the at least one of the first layers at a resonance frequency of the SM-XBAR.

In an exemplary aspect of the bandpass filter, the first thickness of the at least one of the first layers is between 0.26λ₁ to 0.32λ₁.

In an exemplary aspect of the bandpass filter, a second thickness of at least one of the second layers is larger than a quarter of a second wavelength λ₂, and λ₂ is an acoustic wavelength of the shear bulk wave in the at least one of the second layers.

In an exemplary aspect of the bandpass filter, the second thickness of the at least one of the second layers is between 0.26λ₂ to 0.32λ₂.

In an exemplary aspect of the bandpass filter, the first thickness of the at least one of the first layers is between 0.26λ₁ to 0.32λ₁.

In an exemplary aspect of the bandpass filter, the first acoustic impedance of the first materials is larger than the second acoustic impedance of the second materials.

In an exemplary aspect of the bandpass filter, the first thickness of the at least one of the first layers is less than 0.35λ₁.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM-XBAR).

FIG. 3A is a schematic cross-sectional view of an XBAR according to an exemplary aspect.

FIG. 3B is an alternative schematic cross-sectional view of an XBAR according to an exemplary aspect.

FIG. 4A is a graphic illustrating a shear horizontal acoustic mode in an XBAR.

FIG. 4B shows an example of a shear horizontal acoustic mode in an SM-XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 shows an example of an SM-XBAR 600 according to an exemplary aspect of the disclosure.

FIG. 7A shows an example of reflection and transmission of a shear wave incident onto an interface between a piezoelectric layer and an acoustic reflector such as an acoustic Bragg reflector according to an exemplary aspect of the disclosure.

FIG. 7B shows an example of reflection and transmission of a shear wave and a longitudinal wave incident onto an interface between a piezoelectric layer and an acoustic reflector, such as an acoustic Bragg reflector, according to an exemplary aspect of the disclosure.

FIG. 7C illustrates a plot showing the incident angle relative to the pitch to thickness ratio according to an exemplary aspect.

FIGS. 8A-8B show examples of electromechanical coupling indicated by k² varying with a pitch-to-thickness ratio according to some exemplary aspects of the disclosure.

FIG. 9A shows an example of an SM-XBAR 900A according to an exemplary aspect of the disclosure.

FIG. 9B shows an example of an SM-XBAR 900B according to an exemplary aspect of the disclosure.

FIG. 9C shows an example of an SM-XBAR 900C according to an exemplary aspect of the disclosure.

FIG. 10A compares performances of an example of the SM-XBAR in FIG. 6 and an example of the SM-XBAR in FIG. 9A or FIG. 9B according to an aspect of the disclosure.

FIG. 10B shows a heat map style plot indicating a relationship between a quality factor (Qa) and a first thickness of first layers and a second thickness of second layers in the acoustic reflector of the SM-XBAR in FIG. 9A or FIG. 9B.

FIGS. 11 and 12A-12B show plots indicating transmittance of different acoustic reflectors versus a frequency according to an exemplary aspect of the disclosure.

FIG. 13 compares performances of an example of the SM-XBAR 600 and an example of the SM-XBAR 900A according to an exemplary aspect of the disclosure.

FIG. 14 shows a heat map style plot indicating a relationship between Qa and the first thickness of the first layers and the second thickness of the second layers for the SM-XBAR 900A according to an exemplary aspect of the disclosure.

FIGS. 15-17 show an effect of material properties on the optimization of the first thickness and the second thickness in the acoustic Bragg reflector in the SM-XBAR 900A according to an aspect of the disclosure.

FIGS. 18-20 show an effect of a number of layers in the acoustic Bragg reflector 940 according to an aspect of the disclosure.

FIGS. 21A, 21B and 22 shows effects of material properties and the pitch-to-thickness ratio on the optimization of a first thickness and a second thickness in the acoustic Bragg reflector 940 according to an aspect of the disclosure.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

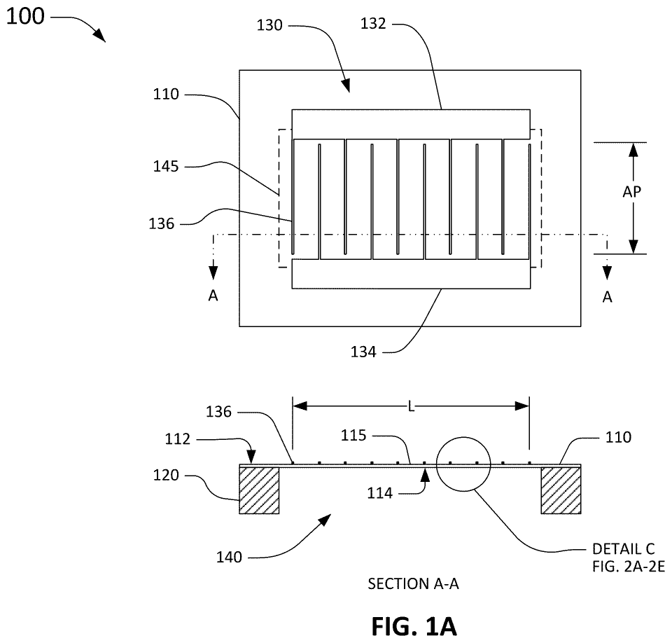

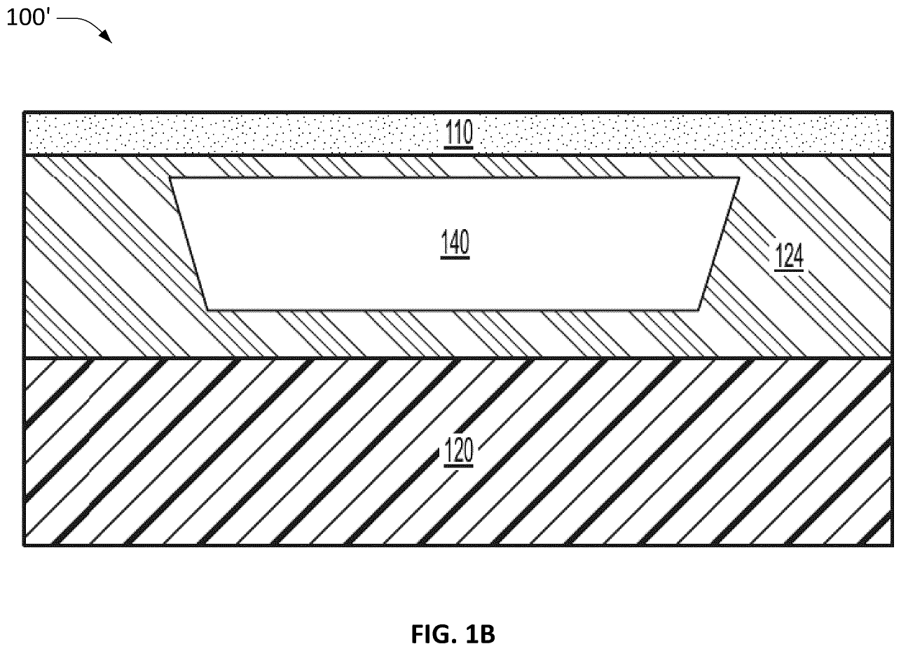

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used generally herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

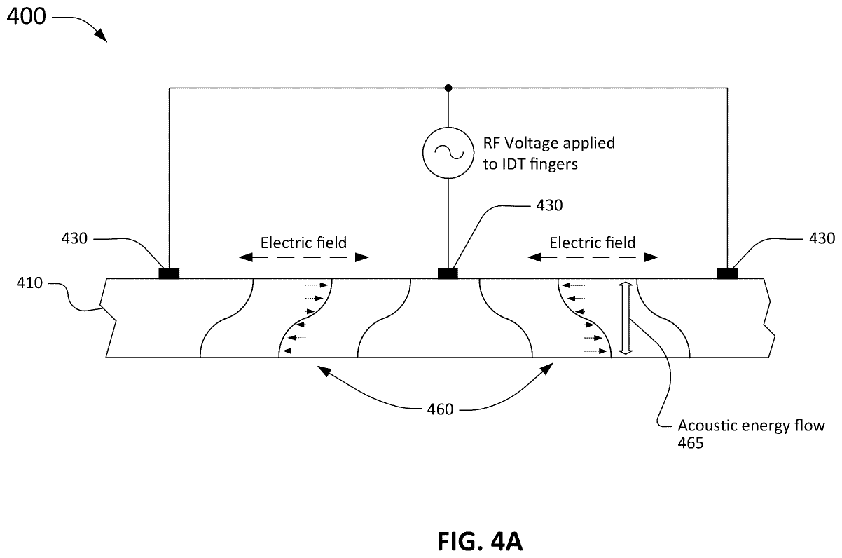

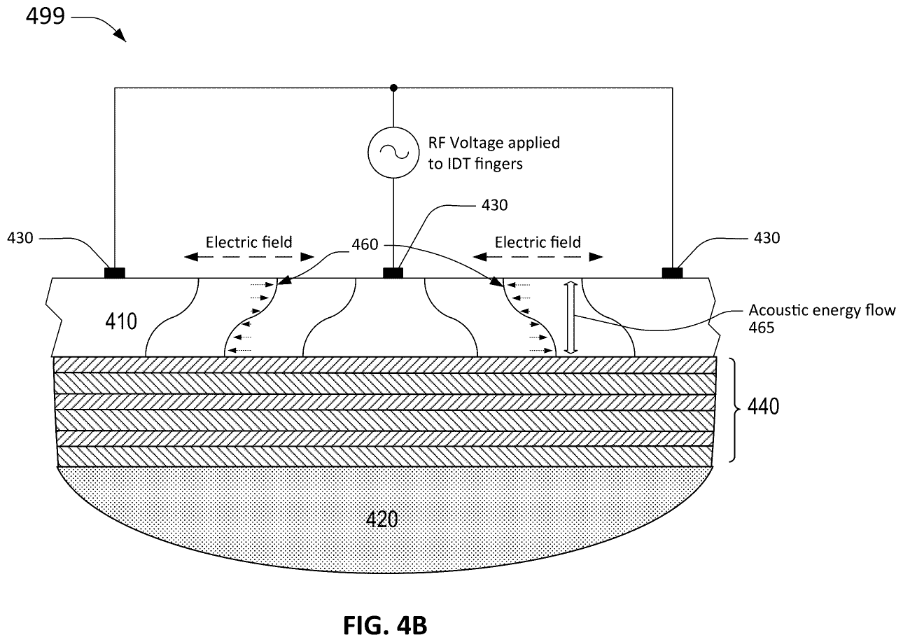

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIGS. 4A-4B.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Sᵢ in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

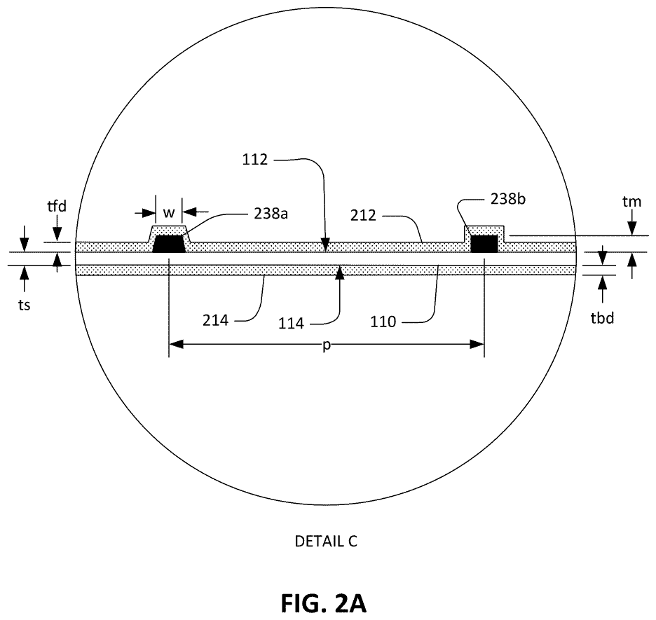

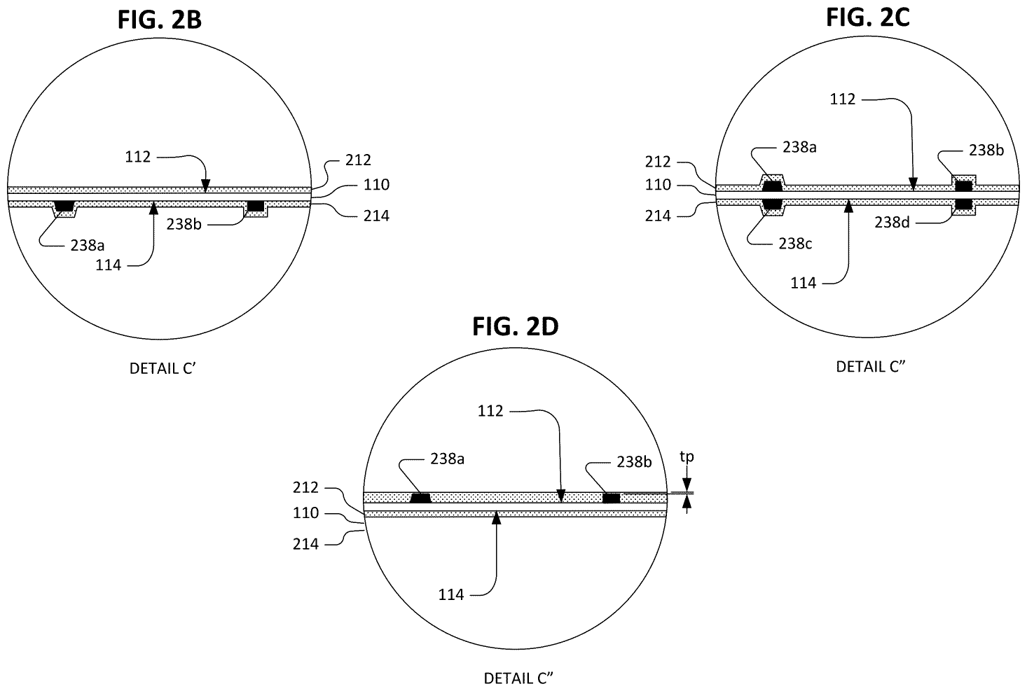

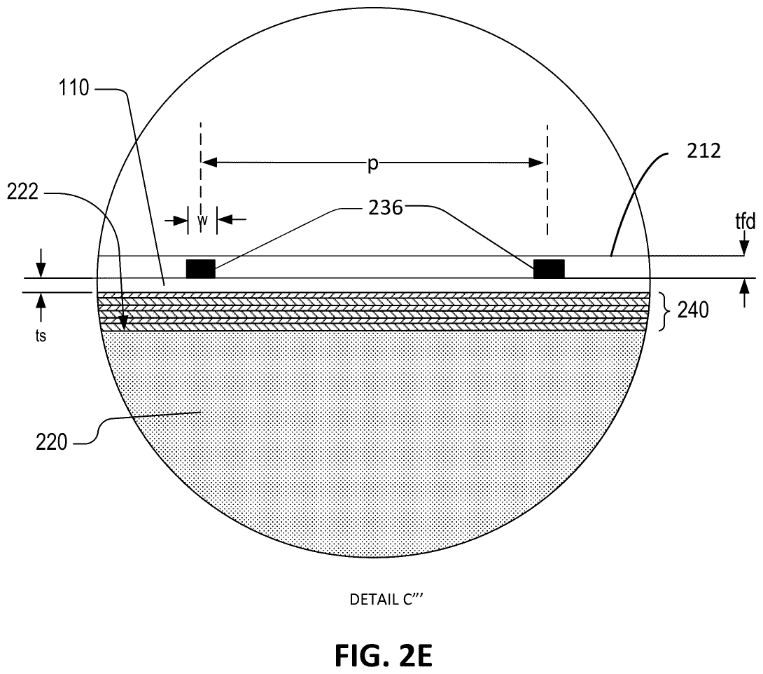

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspect, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIGS. 4A-4B, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can (i.e., on the opposing surfaces of the piezoelectric layer) be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the Piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C″″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a mirror (such as a Bragg mirror), which in turn can be mounted on a substrate.

In particular, FIG. 2E shows a detailed schematic cross-sectional view of a solidly-mounted transversely-excited bulk acoustic resonator (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic reflector 240, such as an acoustic Bragg reflector, is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

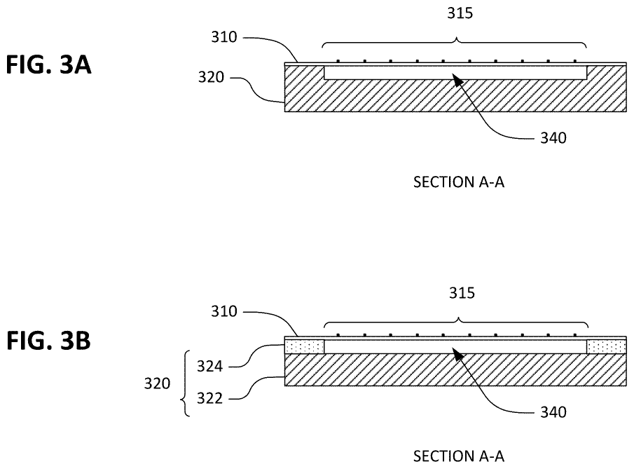

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4A is a graphical illustration of the primarily excited acoustic mode (also referred to as a primary acoustic mode) of interest in an XBAR. FIG. 4A shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” In an example, the direction of the electric field is orthogonal to the length of the IDT fingers. Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4A. While the atomic motions are predominantly lateral (i.e., horizontal as shown in FIG. 4A), the direction of acoustic energy flow of the primarily excited shear acoustic mode is substantially and/or primarily orthogonal to the surface of the piezoelectric layer, as indicated by the arrow 465.

In an aspect, an XBAR may be an SM-XBAR, and the description of the primarily excited acoustic mode in FIG. 4A may be adapted as follows. FIG. 4B shows an example of a shear horizontal acoustic mode in an SM-XBAR 499. The SM-XBAR 499 may include the piezoelectric layer 410 and the IDT fingers 430. The piezoelectric layer 410 and the IDT fingers 430 in FIG. 4B may be identical or similar to the piezoelectric layer 410 and the IDT fingers 430 described in FIG. 4A. The SM-XBAR 499 includes an acoustic reflector such as an acoustic Bragg reflector 440 (also interchangeably referred to as an acoustic Bragg mirror).

In an aspect, the piezoelectric layer 410 and the IDT fingers 430 may be configured such that a radio frequency signal applied to the IDT fingers may excite a primary shear acoustic mode in the piezoelectric layer 410. An electric field is excited in a substantially lateral direction in the piezoelectric layer 410, and wave propagation (indicated by the arrow 465) of the primary shear acoustic mode is perpendicular to the substantially lateral direction of the electric field.

An acoustic Bragg reflector 440 may be sandwiched between the piezoelectric layer 410 and a substrate 420. The acoustic Bragg reflector 440 may reflect the shear acoustic waves to keep the acoustic energy (indicated by the arrow 465) predominantly confined to the piezoelectric layer 410. An example of the acoustic Bragg reflector 440 is the acoustic Bragg reflector 240 described in FIG. 2E. As previously described, the acoustic Bragg reflector 440 may include alternating layers of materials having relatively high and relatively low acoustic impedance. In some examples, each layer has a thickness of about one-quarter of a respective wavelength of the shear acoustic waves (indicated by the arrow 465) at or near a resonance frequency of the SM-XBAR 499. In the example of FIG. 4B, the acoustic Bragg reflector 440 has a total of six layers. An acoustic reflector such as an acoustic Bragg reflector may have more than, or less than, six layers.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

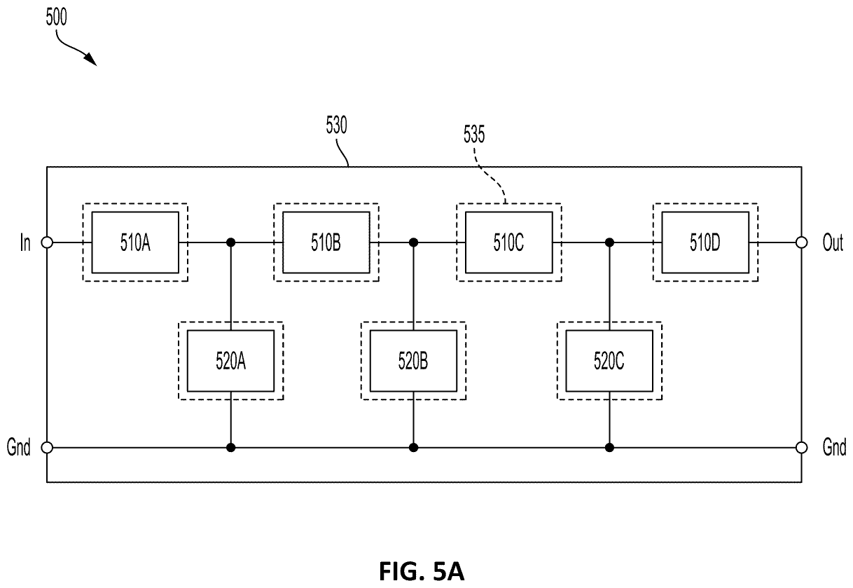

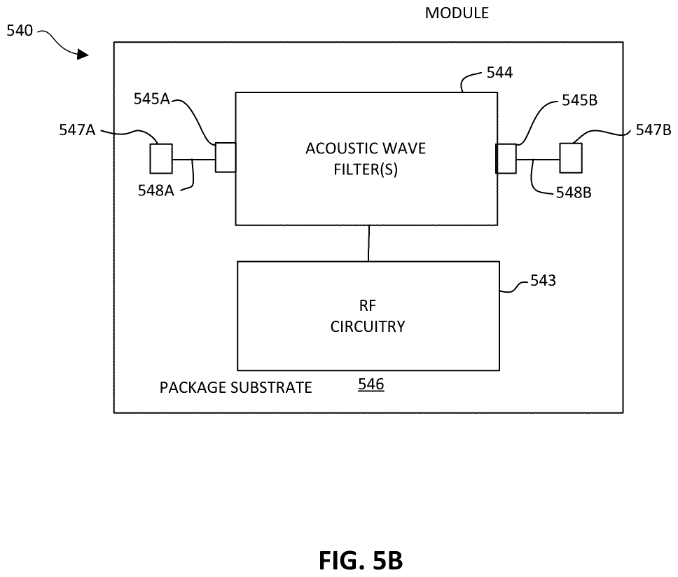

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a mirror such as a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

As described in FIGS. 2E and 4B, an SM-XBAR may include a portion of a piezoelectric layer that is solidly mounted over a substrate with an acoustic mirror, such as an acoustic reflector (e.g., an acoustic Bragg reflector). SM-XBARs may have good power handling capability, mechanical stability, and robustness.

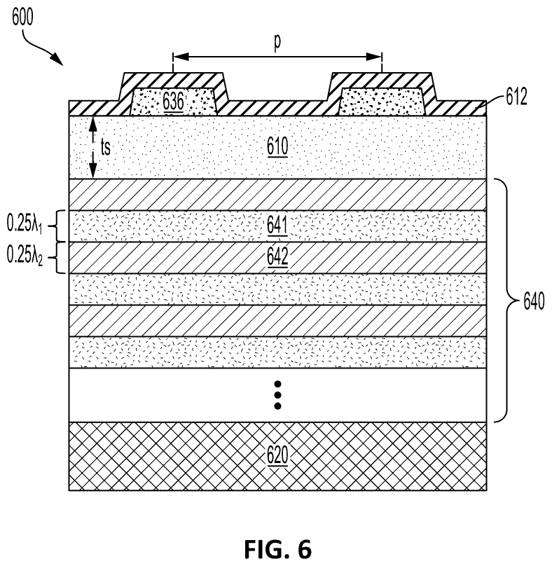

In some examples, an acoustic reflector such as an acoustic Bragg reflector is a quarter-wave Bragg mirror including an alternating sequence of quarter-wavelength thick layers of high and low impedance materials, such as shown in FIG. 6. FIG. 6 shows an example of an SM-XBAR 600. The SM-XBAR 600 may include a piezoelectric layer 610 and an IDT including IDT fingers 636. The IDT fingers 636 may be covered by a dielectric layer 612. The piezoelectric layer 610, the IDT fingers 636, and the dielectric layer 612 in FIG. 6 may be identical or correspond to the piezoelectric layer 110, the IDT fingers 236, and the dielectric layer 212 in FIG. 2E. The SM-XBAR 600 includes an acoustic reflector such as an acoustic Bragg reflector 640.

In general, the acoustic reflector (e.g., the acoustic Bragg reflector) 640 may correspond to the acoustic reflector (e.g., the acoustic Bragg reflector) 440 or the acoustic Bragg reflector 240. In the example shown in FIG. 6, the acoustic Bragg reflector 640 is sandwiched between the piezoelectric layer 610 and a substrate 620. In an example, the substrate 620 is formed using silicon. As previously described, the acoustic Bragg reflector 640 may include alternating layers of materials having relatively high and relatively low acoustic impedance. For example, the acoustic Bragg reflector 640 includes alternating first layers 641 formed of first materials and second layers 642 formed of second materials. A first acoustic impedance of the first materials may be different from a second acoustic impedance of the second materials. In an example, the first acoustic impedance of the first materials is larger than the second acoustic impedance of the second materials, and the first materials are high impedance materials, and the second materials are low impedance materials. In an example, the second materials include silicon oxide, or SiO2. The acoustic Bragg reflector 640 may have any suitable number of layers, such as 5, 6, 7, or the like. The acoustic Bragg reflector 640 may have more than 7 layers or less than 5 layers.

In the example shown in FIG. 6, each layer has a thickness of about one-quarter of a respective wavelength of the shear acoustic waves at a resonance frequency of the SM-XBAR 600. For example, a first thickness of each first layer 641 is a quarter of a first wavelength 21, and thus the first thickness of each first layer 641 is 0.25λ₁. λ₁ is a wavelength of a shear bulk wave in each first layer 641 at a frequency such as the resonance frequency of the SM-XBAR 600, the anti-resonance frequency of the SM-XBAR 600, a frequency between the resonance frequency of the SM-XBAR 600 and the anti-resonance frequency of the SM-XBAR 600, or the like. A second thickness of each second layer 642 is a quarter of a second wavelength λ₂, and thus the second thickness of each second layer 642 is 0.25λ₂. λ₂ is a wavelength of the shear bulk wave in each second layer 642 at the same frequency used in determining λ₁. In some examples, λ₁ and λ₂ are the wavelengths of the shear bulk wave in the first layers 641 and the second layers 642 at the anti-resonance frequency of the SM-XBAR 600, respectively.

In the case shown in FIG. 6, the acoustic Bragg reflector 640 may be designed for an optimal reflection of the shear bulk wave (also referred to as shear acoustic waves, the shear wave, the shear horizontal acoustic mode, or a shear component). For example, the acoustic Bragg reflector 640 may reflect the shear acoustic waves to keep the shear bulk wave predominantly confined to the piezoelectric layer 610. However, in certain acoustic resonator configurations having a small pitch to piezoelectric thickness ratio, the vertical propagating shear wave may become tilted to have a mix of both shear and longitudinal components. Moreover, these longitudinal component of the main mode can then pass through the Bragg mirror if it is not properly designed and configured to reflect the longitudinal waves as well. As a result, the acoustic Bragg reflector 640 may not be configured to adequately reflect a longitudinal wave (also referred to as a longitudinal component), and thus loss of the longitudinal component in the main mode may be relatively larger than the loss of the shear bulk wave.

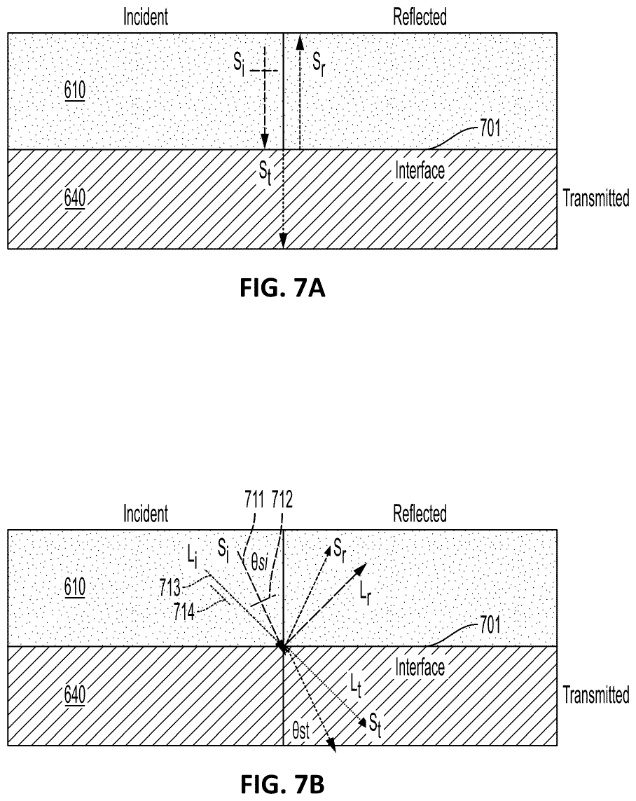

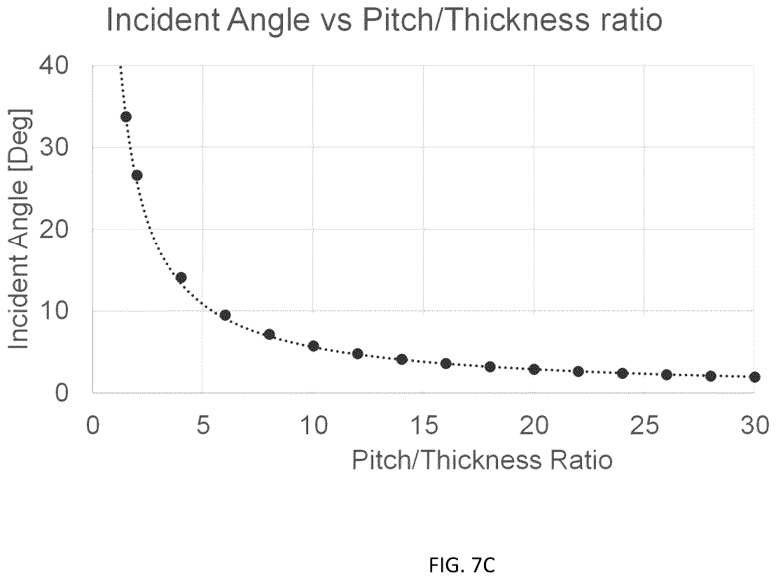

FIG. 7A shows an example of reflection and transmission of a shear wave Sᵢ incident onto an interface 701 between the piezoelectric layer 610 and the acoustic Bragg reflector 640 according to an aspect of the disclosure. In some examples, FIG. 7A shows an ideal case where a ratio (e.g., also referred to as a pitch-to-thickness ratio) of a pitch p between two adjacent IDT fingers 636 of the IDT over a thickness ts of the piezoelectric layer 610 is infinite. In this case, a vertically propagating acoustic wave (e.g., Sᵢ) is at normal incidence (e.g., an incident angle θᵢ that is between a propagation direction of the acoustic wave and a surface norm of the interface 701 being 0), and only a shear wave Sᵢ is present. For example, the vertically propagating acoustic wave is the shear wave Sᵢ. Referring to FIG. 7A, a first portion of the shear wave Sᵢ is reflected as a reflected shear wave Sᵣ, and a first portion of the shear wave Sᵢ is transmitted into the acoustic Bragg reflector 640 as a transmitted shear wave St. The acoustic Bragg reflector 640 may be designed for an optimal reflection of the shear wave Sᵢ as described above, and thus the reflected shear wave Sᵣ predominates the transmitted shear wave Sₜ. In various examples, when the pitch-to-thickness ratio is relatively large, such as larger than 20, the incident acoustic wave is substantially normal to the interface 701, similarly to case shown in FIG. 7A, and the incident acoustic wave is predominately the incident shear wave.

When a resonator, such as the SM-XBAR 600, has a relatively small pitch-to-thickness ratio, the incident acoustic wave may become “tilted”, such as shown in FIG. 7B. In particular, FIG. 7B shows an example of reflection and transmission of a shear wave Sᵢ and a longitudinal wave Lᵢ incident onto the interface 701 between the piezoelectric layer 610 and the acoustic Bragg reflector 640 according to an aspect of the disclosure. When the pitch-to-thickness ratio of the pitch p over the thickness ts is relatively small, for example, the pitch-to-thickness ratio is less than a threshold such as 10, the incident acoustic wave may not be perpendicular to the interface 701 (e.g., the incident acoustic wave is angled with respect to the interface 701), the incident acoustic wave may be partially converted into a longitudinal wave at the interface 701. In some cases, the incident acoustic wave of FIG. 7A already includes a longitudinal component, but at pitch-to-thickness ratios of less than 10, a magnitude of conversion of the incident acoustic wave into a longitudinal component may be increased such that a larger longitudinal component exists, as generally illustrated in FIG. 7B. Referring to FIG. 7B, the incident acoustic wave may include a shear wave component (also referred to as a shear wave) Sᵢ and a longitudinal component (also referred to as a longitudinal wave) Lᵢ.

FIG. 7C illustrates a plot showing the incident angle relative to the pitch to thickness ratio according to an exemplary aspect. It is noted that the plot can be simulated using finite element method (FEM) simulation techniques, where the X axis is for the pitch (of the IDT) to thickness (of the piezoelectric layer) ratio and the Y axis is for the incident angle (in degrees). As shown, at a pitch-to-thickness ratio that is below 10, the wave starts to become significantly “tilted”, which indicates that the longitudinal component becomes larger. On the other hand, and as described in more detail below, using a relatively small pitch-to-thickness ratio (e.g., less than 10) may be advantageous as the maximal Qa for the relatively small pitch-to-thickness ratio (e.g., less than 10) may be larger than the maximal Qa for the relatively large pitch-to-thickness ratio (e.g., larger than 10).

In general, when the incident wave propagates at an incident angle that is not zero, the incident wave may be partially converted to a longitudinal wave at the interface 701. Referring back to FIG. 7B, the shear wave Sᵢ is incident onto the interface 701 at an incident angle θₛᵢ (θₛᵢ is not zero), a portion of the shear wave Sᵢ is reflected as a reflected shear wave Sr, and a portion of the shear wave Sᵢ is transmitted into the acoustic Bragg reflector 640 as a transmitted shear wave St with a transmission angle θₛₜ. The longitudinal wave Lᵢ is incident onto the interface 701 at an incident angle θₗᵢ (θₗᵢ is not zero), a portion of the longitudinal wave Lᵢ is reflected as a reflected longitudinal wave Lᵣ, and a portion of the longitudinal wave Lᵢ is transmitted into the acoustic Bragg reflector 640 as a transmitted longitudinal wave Lₜ with a transmission angle θₜₜ. In some examples, the incident angle θₗᵢ is larger than the incident angle θₛᵢ. An incident angle may be different from a transmitted angle, for example, due to refraction. Thus, θₛᵢ is different from θₛₜ, and θₗᵢ is different from Ott. The angles θₛᵢ and θₛₜ are exaggerated in FIG. 7B. In some examples, θₛᵢ and θₛₜ are less than 5°.

Referring to FIG. 7B, a propagation direction 711 of the shear wave Sᵢ may be perpendicular to a displacement direction 712. The propagation direction 711 indicates the direction of acoustic energy flow of the shear wave Sᵢ (e.g., indicated by the arrow 465 in FIG. 4B), and the displacement direction 712 indicates a direction of the shear deformations represented by the curves 460 in FIG. 4B. In contrast, a propagation direction 713 of the longitudinal wave Lᵢ may be parallel to a displacement direction 714. The propagation direction 713 indicates the direction of acoustic energy flow of the longitudinal wave Lᵢ, and the displacement direction 714 indicates a direction of atomic motion in the medium (e.g., the piezoelectric layer 610).

Referring back to FIG. 6, the thicknesses of the layers in the acoustic Bragg reflector 640 may be improved for the shear wave Sᵢ, especially for the shear wave Sᵢ having a relatively small incident angle θₛᵢ, for example, the first thickness of each first layer 641 is 0.25λ₁ and the second thickness of each second layer 642 is 0.25λ₂. Thus, the SM-XBAR 600 may be efficient when the pitch-to-thickness ratio is relatively large (e.g., the pitch-to-thickness ratio is larger than 20).

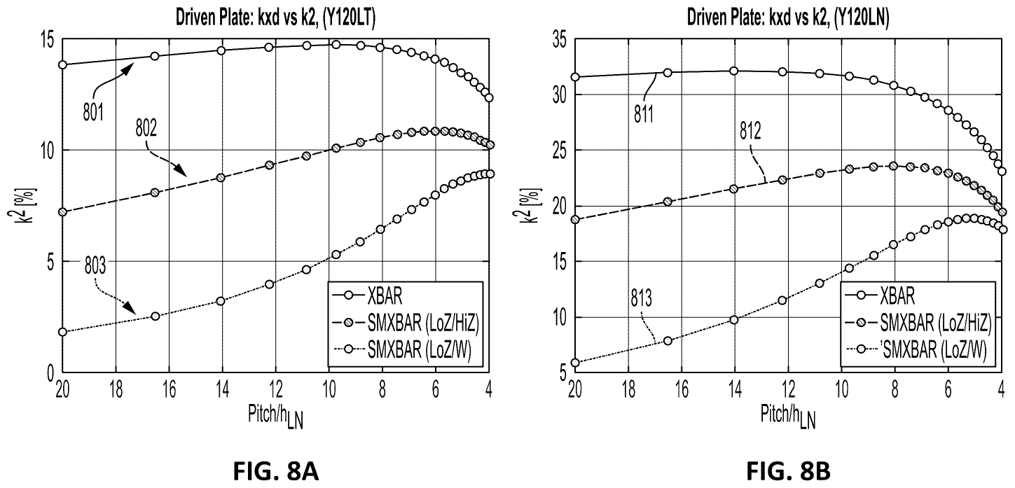

In some examples, electromechanical coupling such as indicated by k² may vary with the pitch-to-thickness ratio, such as shown in FIGS. 8A-8B according to some aspects of the disclosure. It is noted that the plots in FIGS. 8A and 8B can be simulated using finite element method (FEM) simulation techniques,

Referring to FIG. 8A, a curve 801 indicates a relationship of the coupling k² of a first example of the XBAR 100 versus the pitch-to-thickness ratio where the piezoelectric layer 110 of the first example of the XBAR 100 is disposed over the cavity 140. k² of the first example of the XBAR 100 increases with a decrease of the pitch-to-thickness ratio and reaches a maximal coupling k² approximately at the pitch-to-thickness ratio being 10. A curve 802 indicates a relationship of the coupling k² of a first example of the SM-XBAR 600 versus the pitch-to-thickness ratio. k² of the first example of the SM-XBAR 600 increases with a decrease of the pitch-to-thickness ratio and reaches a maximal coupling k² approximately at the pitch-to-thickness ratio being 6. A curve 803 indicates a relationship of the coupling k² of a second example of the SM-XBAR 600 versus the pitch-to-thickness ratio. Referring to the curve 803, k² of the second example of the SM-XBAR 600 increases with a decrease of the pitch-to-thickness ratio until k² reaches a maximal coupling approximately at the pitch-to-thickness ratio being 4.

The piezoelectric layer 110 or the piezoelectric layer 610 described in reference to FIG. 8A includes lithium tantalate and has Euler angles [0°, 30°, 0°] and is referred to as “120Y.”

The piezoelectric layer 110 or the piezoelectric layer 610 described in reference to FIG. 8B includes lithium niobate and has Euler angles [0°, 30°, 0°] and is referred to as “120Y.”

Referring to FIG. 8B, a curve 811 indicates a relationship of the coupling k² of a second example of the XBAR 100 versus the pitch-to-thickness ratio. k² of the second example of the XBAR 100 increases with a decrease of the pitch-to-thickness ratio and reaches a maximal coupling k² approximately at the pitch-to-thickness ratio being 14. A curve 812 indicates a relationship of the coupling k² of a third example of the SM-XBAR 600 versus the pitch-to-thickness ratio. k² of the third example of the SM-XBAR 600 increases with a decrease of the pitch-to-thickness ratio and reaches a maximal coupling k² approximately at the pitch-to-thickness ratio being 8. A curve 813 indicates a relationship of the coupling k² of a fourth example of the SM-XBAR 600 versus the pitch-to-thickness ratio. Referring to the curve 813, k² of the fourth example of the SM-XBAR 600 increases with a decrease of the pitch-to-thickness ratio until k² reaches a maximal coupling approximately at the pitch-to-thickness ratio being 5.

Table 1 shows configurations of the XBAR 100 and SM-XBAR 600 used in FIGS. 8A-8B. Referring to Table 1 and FIG. 6, the first example of the SM-XBAR 600 and the second example of the SM-XBAR 600 are identical except that the first layer 641 in the first example of the SM-XBAR 600 includes high impedance dielectric materials and the first layer 641 in the second example of the SM-XBAR 600 includes metallic materials. Comparing the curves 801-803, the coupling k² of the SM-XBAR 600 (e.g., indicated by the curves 802-803) reaches the maximal coupling at a smaller pitch-to-thickness ratio than that for the coupling k² of the XBAR 100 (e.g., indicated by the curve 801).

TABLE 1
Configurations of the XBAR 100 and SM-XBAR 600 used in FIGS. 8A-8B

| Curve | 801 | 802 | 803 | 811 | 812 | 813 |
|---|---|---|---|---|---|---|
| XBAR | 100 | 600 | 600 | 100 | 600 | 600 |
| Configuration | Example 1 | Example 1 | Example 2 | Example 2 | Example 3 | Example 4 |
| Piezoelectric | 110 | 610 | 610 | 110 | 610 | 610 |
| layer | Lithium | Lithium | Lithium | Lithium | Lithium | Lithium |
| | Tantalate | Tantalate | Tantalate | Niobate | Niobate | Niobate |
| First layer | N/A | High | Metallic | N/A | High | Metallic |
| 641 | | Impedance | Material | | Impedance | Material |
| | | Dielectric | | | Dielectric | |
| | | Material | | | Material | |
| Second layer | N/A | Low | Low | N/A | Low | Low |
| 642 | | Impedance | Impedance | | Impedance | Impedance |
| | | Dielectric | Dielectric | | Dielectric | Dielectric |
| | | Material | Material | | Material | Material |

Referring to Table 1 and FIG. 6, the third example of the SM-XBAR 600 and the fourth example of the SM-XBAR 600 are identical except that the first layer 641 in the third example of the SM-XBAR 600 includes high impedance dielectric materials and the first layer 641 in the fourth example of the SM-XBAR 600 includes metallic materials. Comparing the curves 811-813, the coupling k² of the SM-XBAR 600 (e.g., indicated by the curves 812-813) reaches the maximal coupling at a smaller pitch-to-thickness ratio than that for the coupling k² of the XBAR 100 (e.g., indicated by the curve 811).

In some scenarios, such as shown in FIGS. 8A-8B, it may be beneficial to use the SM-XBAR 600 having a smaller pitch-to-thickness ratio, for example, to increase coupling k². As indicated by the curves 802-803 and 812-813, the SM-XBAR 600 may reach a maximal coupling k² when the pitch-to-thickness ratio is relatively small, such as less than 10.

However, in some examples, the SM-XBAR 600 may not be efficient when the pitch-to-thickness ratio is relatively small (e.g., the pitch-to-thickness ratio is less than 10). Referring to FIG. 7B, when the pitch-to-thickness ratio is relatively small such as less than a threshold value (e.g., 10), the vertically propagating acoustic wave may become tilted and the acoustic wave may become “mixed” having both the shear component Sᵢ and the longitudinal component Lᵢ, and the longitudinal wave Lᵢ may easily pass through the acoustic Bragg reflector 640 if the acoustic Bragg reflector 640 is not properly designed to reflect both the shear wave Sᵢ and the longitudinal wave Li. Thus, the SM-XBAR 600 may have a relatively low-quality factor (e.g., Q factor).

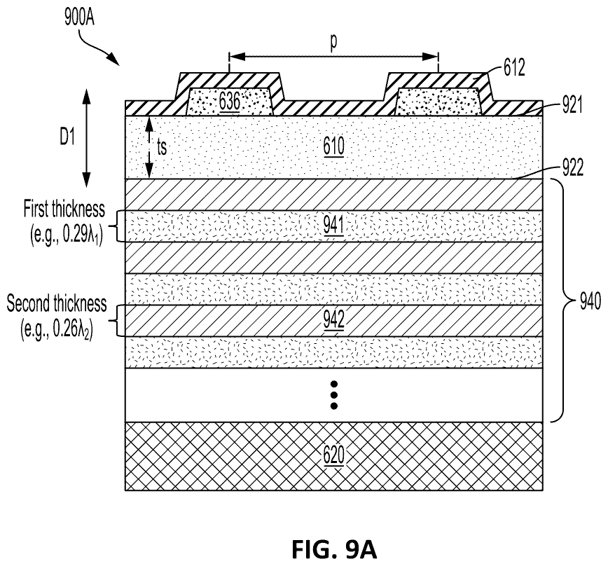

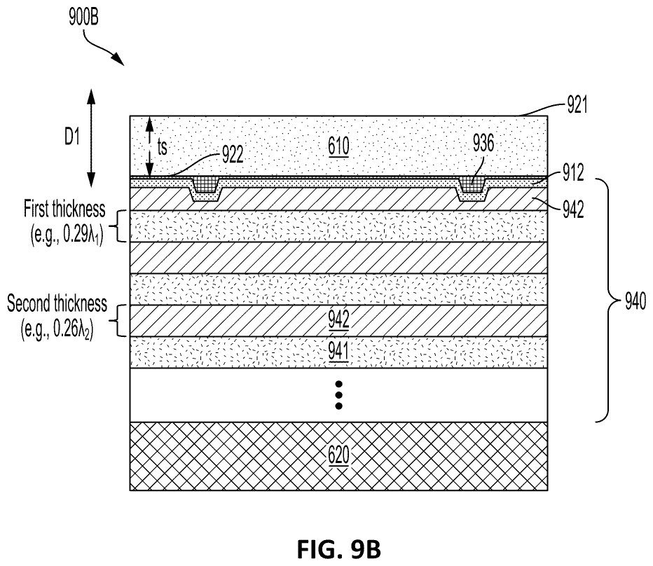

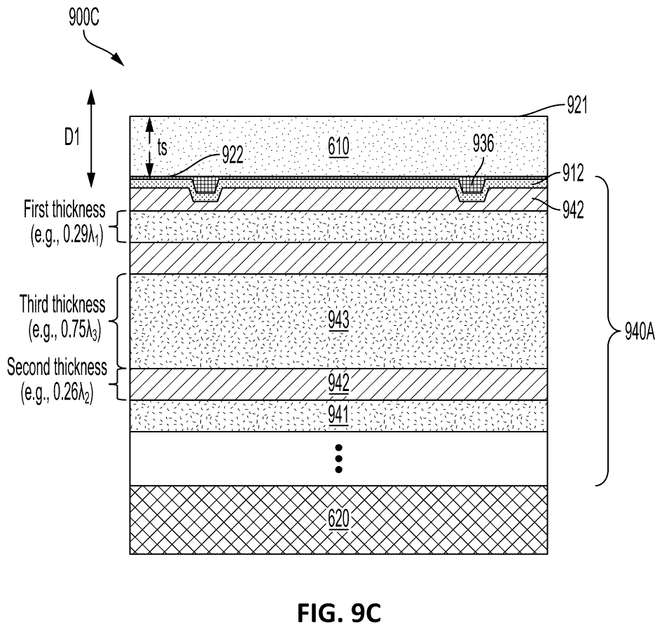

An aspect of the disclosure describes optimal layer thicknesses of high impedance materials and low impedance materials in an acoustic Bragg reflector, and thus the acoustic Bragg reflector may provide optimal reflections for both the shear and longitudinal waves to achieve a higher Q resonator, such as shown in FIGS. 9A-9B.

FIG. 9A shows an example of an SM-XBAR 900A where an IDT (e.g., an IDT including IDT fingers 636) and an acoustic Bragg reflector 940 are disposed on different sides of a piezoelectric layer. FIG. 9B shows an example of an SM-XBAR 900B where an IDT including IDT fingers 936 and the acoustic Bragg reflector 940 are disposed on a same side of the piezoelectric layer 610 according to an aspect of the disclosure.

Referring to FIG. 9A, the SM-XBAR 900A may include the piezoelectric layer 610 and the IDT including IDT fingers 636. The IDT fingers 636 may be covered by the dielectric layer 612. The piezoelectric layer 610, the IDT fingers 636, and the dielectric layer 612 in FIG. 9A are described in FIG. 6. The SM-XBAR 900A includes an acoustic Bragg reflector 940. In an example, the acoustic Bragg reflector 940 is sandwiched between the piezoelectric layer 610 and the substrate 620. It is noted that while the SM-XBAR 900A (and the other exemplary aspects described below) has fingers 636 that form a configuration similar to IDT 130 as described above, the exemplary configuration can have alternate IDT configurations in which the exemplary Bragg reflector 940 can still be implemented. For example, in alternative aspects electrodes of the IDT with positive and negative potentials can be disposed on each side of the piezoelectric layer, similar to the configuration described above with respect to FIG. 2C. In yet another aspect, electrodes with positive and negative potentials can be disposed on one side of the piezoelectric layer while a floating electrode can be disposed on the other side of the piezoelectric layer. As such, the particular IDT configuration of the exemplary aspects should not be so limited.

Moreover, in an example, the term “sandwiched” means the acoustic Bragg reflector 940 is both disposed between and mechanically attached to a surface of the substrate 620 and the second surface 922 of the piezoelectric layer 610. In some circumstances, layers of additional materials may be disposed between the acoustic Bragg reflector 940 and the surface of the substrate 620 and/or between the acoustic Bragg reflector 940 and the second surface 922 of the piezoelectric layer 610. Such additional material layers may be present, for example, to facilitate bonding the piezoelectric layer 610, the acoustic Bragg reflector 940, and the substrate 620.

Referring to FIG. 9B, the SM-XBAR 900B may include the piezoelectric layer 610 and the IDT including IDT fingers 936. The IDT including the IDT fingers 936 may be covered by a dielectric layer 912. In an example, the IDT including the IDT fingers 936 may be disposed within a top layer (such as a second layer 942) in the acoustic Bragg reflector 940.

Referring to FIGS. 9A-9B, the acoustic Bragg reflector 940 may include alternating first layers 941 of first materials and second layers 942 of second materials that are of a different material than the first materials. In an aspect, a first acoustic impedance of the first materials may be different from a second acoustic impedance of the second materials. In an example, the first acoustic impedance of the first materials is larger than the second acoustic impedance of the second materials, and the first materials are high impedance materials, and the second materials are low impedance materials. In an example, the second materials include SiO2. The acoustic Bragg reflector 940 may have any suitable number of layers, such as 5, 6, 7, or the like. The acoustic Bragg reflector 940 may have more than 7 layers or less than 5 layers.

In an exemplary aspect, the first layers 941 may be formed of a low acoustic impedance as described herein and the second layers 942 may be formed of a high acoustic impedance as described herein or vice versa. For example, dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. It is also noted that all of the first layers 941 may be the same or a different material as each other. Similarly, all of the second layers 942 may be the same or a different material as each other. Moreover, one or some of the first layers 941 and/or second layers 942 may be a metal layer, such as tungsten or titanium, for example, to further facilitate the reflective configuration. It is also generally noted that either the high acoustic impedance layer or the low acoustic impedance layer can be the top layer of the Bragg reflector 940 that is closest the piezoelectric layer and IDT configuration.

Referring to FIGS. 9A-9B, λ₁ is the acoustic wavelength of a shear bulk wave in a specific material, such as within the material of each first layer 941 at a frequency such as the resonance frequency of the SM-XBAR 900A (or 900B), the anti-resonance frequency of the SM-XBAR 900A (or 900B), a frequency between the resonance frequency of the SM-XBAR 900A (or 900B) and the anti-resonance frequency of the SM-XBAR 900A (or 900B), or the like, and λ₂ is a acoustic wavelength of the shear bulk wave in a specific material, such as within the material of each second layer 942 at the same resonance frequency used in determining M. In some examples, λ₁ and λ₂ are the acoustic wavelengths of the shear bulk wave in the first layers 941 and the second layers 942 at the anti-resonance frequency of the SM-XBAR 900A (or 900B), respectively. An example of the shear bulk wave in a piezoelectric layer is described in FIG. 4B.

According to an aspect of the disclosure, when the pitch-to-thickness ratio of the pitch p between two adjacent IDT fingers 636 over the thickness ts of the piezoelectric layer 610 is less than a threshold of 10, a first thickness of at least one of the first layers 941 and/or a second thickness of at least one of the second layers 942 may be determined such that the acoustic Bragg reflector 940 may reflect the shear wave and the longitudinal wave with relatively high reflectivity, and thus confining the acoustic energy predominately within the piezoelectric layer 610. In an aspect, the thickness ts of the piezoelectric layer 610, the first thickness of the at least one of the first layers 941, the second thickness of the at least one of the second layers 942 may be measured in a direction D1 that is orthogonal to a first surface 921 and/or to a second surface 922 of the piezoelectric layer 610.

In the example shown in FIGS. 9A-9B, the first thickness of the at least one of the first layers 941 is 0.29λ₁ and the second thickness of the at least one of the second layers 942 is 0.26λ₂. Referring to FIG. 9B, in an example, the thickness of the top layer in the acoustic Bragg reflector 940 is identical to the second thickness of the at least one of the second layers 942. In an example, the thickness of the top layer in the acoustic Bragg reflector 940 is different from the second thickness of the at least one of the second layers 942. It should be appreciated that in some exemplary aspects, all of the first layers 941 may have the same thickness as each other and all of the second layers 942 may have the same thickness as each other. However, in alternative aspects, the thicknesses may be varied amongst the first layers 941 and similarly the thicknesses may be varied amongst the second layers 942. More specifically, varying one of the layers allows for a specific benefit which increases reflection of a longitudinal component of an excited primarily shear acoustic wave, as discussed below in reference to FIG. 9C. In some cases, the reflective configuration and efficiency is based on the particular materials being used for the layers of the Bragg reflector 940.

In an aspect, the first thickness of the at least one of the first layers 941 is larger than a quarter of the first acoustic wavelength λ₁ (i.e., larger than 0.25λ₁), and the shear bulk wave has a same polarization as a primary acoustic mode of the SM-XBAR 900A or 900B. In an example, the first thickness of the at least one first layer 941 may be from 0.26λ₁ to 0.32λ₁.

In an aspect, the second thickness of the at least one of the second layers is larger than a quarter of the second acoustic wavelength λ₂ (i.e., larger than 0.25λ₂). For example, the second thickness of the at least one second layer is from 0.26λ₂ to 0.32λ₂.

In an example, the first thickness of the at least one first layer is from 0.26λ₁ to 0.32λ₁ and the second thickness of the at least one second layer is from 0.26λ₂ to 0.32λ₂.

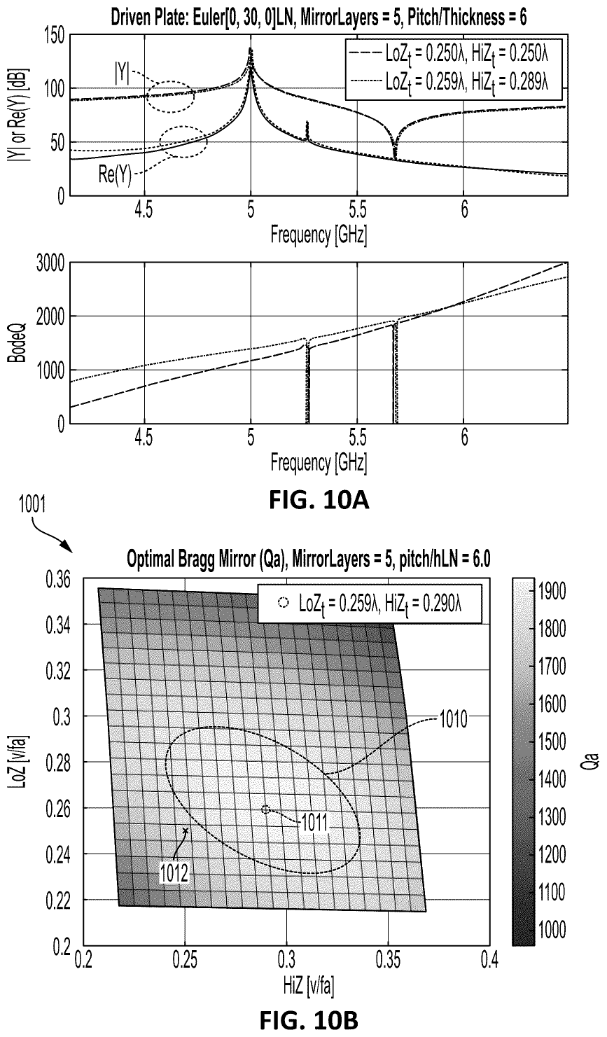

In an aspect, the first acoustic impedance of the first materials is larger than the second acoustic impedance of the second materials, and the first materials in the first layers 941 are high impedance materials and the second materials in the second layers 942 are low impedance materials such as a silicon oxide. When the first acoustic impedance of the first materials is larger than the second acoustic impedance of the second materials, the first thickness may be indicated as high impedance “HiZ”, and the second thickness may be indicated as low impedance “LoZ”, such as in FIGS. 10B and 14-20.

In an aspect, the first thickness of the at least one first layer 941 is less than 0.35λ₁, for example, when the first materials in the first layers 941 are high impedance materials.

In an example, when the first materials in the first layers 941 are high impedance materials and the second materials in the second layers 942 are low impedance materials, the first thickness HiZ of the at least one first layer 941 is less than 0.35λ₁, and the second thickness LoZ of the at least one of the second layers is from 0.22λ₂ to 0.32λ₂.

In an aspect, the acoustic Bragg reflector 940 is adjacent to the second surface 922 of the piezoelectric layer 610. In an example, the acoustic Bragg reflector 940 is between the second surface 922 of the piezoelectric layer 610 and the substrate 620.

In some examples, the first layers 941 may have an identical first thickness HiZ. In some examples, the second layers 942 may have an identical second thickness LoZ, and the two thicknesses HiZ and LoZ may be determined such that the acoustic Bragg reflector 940 may have relatively large reflectivity for both the shear component and the longitudinal component.

In some examples, the first layers 941 may have different first thicknesses. In some examples, the second layers 942 may have different second thicknesses. Thus, the first thicknesses and/or the second thicknesses may be determined such that the acoustic Bragg reflector 940 may have relatively large reflectivity for both the shear component and the longitudinal component.

In the example shown in FIGS. 9A-9B, one of the second layers 942 is disposed between the piezoelectric layer 610 and one of the first layers 941. Other configurations or ordering between the first layers 941 and the second layers 942 may be used in an SM-XBAR. For example, one of the first layers 941 may be disposed between the piezoelectric layer 610 and one of the second layers 942.

It is also noted that one or more layers of the Bragg reflector 940 may have a thickness that is substantially larger than the other layers. Specifically, FIG. 9C shows an example of an SM-XBAR 900C according to an exemplary aspect of the disclosure. As shown, the SM-XBAR 900C has a similar configuration as SM-XBAR 900B described above with respect to FIG. 9B. Therefore, a description of the same components will not be repeated herein.

In the exemplary aspect of SM-XBAR 900C, the Bragg reflector 940A includes one or more layers with thicknesses that differ from the conventional quarter-wavelength design. In particular, at least one layer 943 or more may have a thickness substantially greater than that of the other layers in the mirror stack. The thickness of layer 943 may be greater than approximately 0.25λ and extend to less than 0.75%, where λ corresponds to the acoustic wavelength of the shear wave in that layer at the resonance frequency. In some cases, the range may be greater than 0.25λ and exceed 0.75λ. According to the exemplary aspect, the thicker layer 943 of SM-XBAR 900C is typically not be the first or second layer that is closest to the top of the Bragg reflector 940A and adjacent to the piezoelectric layer 610. Instead, the thicker layer 943 can be the third or fifth layer (e.g., from the top of the Bragg reflector 940A) to adequately improve the reflection of longitudinal waves. Moreover, when layer 943 is made from the same material as the first or second layers, the λ reference is adjusted accordingly (i.e., λ₁ or λ₂). This increased thickness can be used to improve reflection of longitudinal acoustic waves, aiding in mirror optimization. In yet further embodiments, more than one layer may deviate from the standard thickness, and that such variations may occur at any position in the mirror stack as part of an overall design strategy. For example, an optimized mirror may have layers with thicknesses such as 0.3λ, 0.33λ, 0.3λ, 0.68λ, 0.25λ, 0.25λ, 0.25λ or 0.3λ, 0.32λ, 0.7λ, 0.3λ, 0.25λ, 0.25λ, 0.25λ.

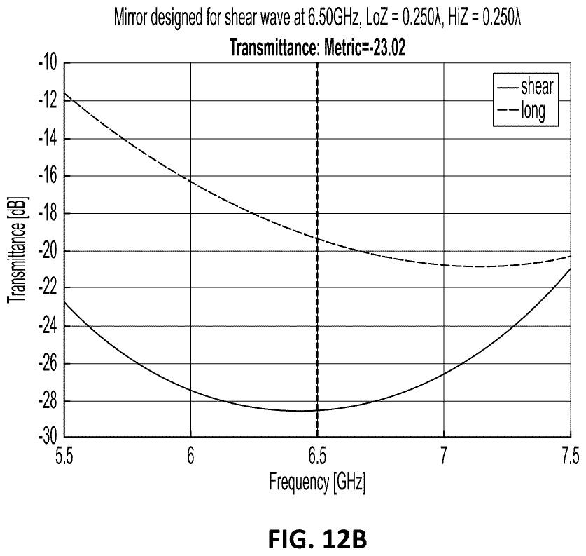

According to this exemplary aspect, it is noted that the term “approximately” in this exemplary aspect takes into account manufacturing variances and can be ±10% of the third-quarter wavelength in an exemplary aspect. Moreover, as discussed below with respect to FIG. 12B, the increased thickness of the at least one additional layer 943 can further improve the reflectivity of the longitudinal component of the main mode in certain exemplary aspects. It is also noted that in some cases, the thicker at least one additional layer 943 may be placed further down in the Bragg stack as opposed to at the top of the Bragg stack. In other words, there is some benefit to placing the thicker layer, such as the at least one additional layer 943, lower than the layer adjacent to the piezoelectric layer 610 either directly or having at least one dielectric layer, such as the second layer 942, between the adjacent layer and the piezoelectric layer 610. It is also noted that while the IDT of SM-XBAR 900C is shown to have a similar configuration as SM-XBAR 900B (e.g., interleaved fingers facing the Bragg reflector 940A), in an alternative aspect, the IDT of SM-XBAR 900C may have a similar configuration as SM-XBAR 900A (e.g., interleaved fingers facing away from the Bragg reflector 940A).

Next, FIG. 10A compares performances of an example of the SM-XBAR 600 and an example of the SM-XBAR 900A or 900B according to an aspect of the disclosure. It is noted that each of the plot and graphs described as follows for FIG. 10A through FIG. 22 is simulated data that can be generated using finite element method (FEM) simulation techniques, for example.

Referring specifically to FIG. 10A, for each of the SM-XBAR 600 and the SM-XBAR 900A or 900B, the pitch-to-thickness ratio is 6, and the piezoelectric layer 610 has Euler angles [0°, 30°, 0°] and is referred to as “120Y.” In an example, the piezoelectric layer 610 includes lithium niobate. A number of layers in each of the acoustic Bragg reflector 640 and the acoustic Bragg reflector 940 is 5.

In the example of the SM-XBAR 600, each first thickness of the first layers 641 is 0.25λ₁ and each second thickness of the second layers 642 is 0.25λ₂ as shown in FIG. 6. In the example of the SM-XBAR 900A or 900B, each first thickness of the first layers 941 is 0.289λ₁ and each second thickness of the second layers 942 is 0.259λ₂.

The top graphs show admittance (interchangeably referred to as a Y-parameter) curves of the SM-XBAR 600 and the SM-XBAR 900A (or 900B) versus a frequency in unit of Giga-Herz (GHz) according to some examples of the disclosure. The frequency range is from approximately 4 to 6.5 GHz. Both the absolute values IYI of the Y-parameters and the real components Re(Y) of the Y-parameters are plotted. The Y-parameters in FIG. 10A indicate that the SM-XBAR 900A (or 900B) and the SM-XBAR 600 have a resonance frequency at approximately 5 GHZ, and an anti-resonance frequency at approximately 5.7 GHZ.

A BodeQ refers to a Q factor calculated from a Bode plot and thus may indicate performance of a resonator such as an SM-XBAR. The bottom graphs in FIG. 10A show BodeQ plots versus the frequency. The BodeQ plot in dots corresponds to the SM-XBAR 900A or 900B and the BodeQ plot in long dashes corresponds to the SM-XBAR 600. The BodeQ plots indicate that Q factors of the SM-XBAR 900A (or 900B) are higher than Q factors of the SM-XBAR 600 at the resonance frequency and the anti-resonance frequency, respectively. For example, Qr that is the BodeQ at the resonance frequency and Qa that is the BodeQ at the anti-resonance frequency of the SM-XBARs 600 and 900 are shown in Table 2.

TABLE 2
Q factors of the SM-XBAR 600 and
the SM-XBAR 900A (or 900B)

| | Qr | Qa |
|---|---|---|
| SM-XBAR 600 having the acoustic Bragg | 1,178 | 1,856 |
| reflector 640 | | |
| SM-XBAR 900A or 900B having the acoustic Bragg | 1,398 | 1,933 |
| reflector 940 | | |

Table 2 indicates that the SM-XBAR 900A or 900B with the improved thicknesses are more efficient than the SM-XBAR 600. More specifically, each of the layer thicknesses of the Bragg reflector in the exemplary aspects can be defined and configured to more efficiently reflect the longitudinal component of the main mode of the bulk acoustic reflector than SM-XBAR 600.

To determine an optimal pair of the first thickness of the first layers 941 and the second thickness of the second layers 942, Q factors (such as Qa) are determined (e.g., calculated) at a frequency (e.g., the anti-resonant frequency) for various combinations of the first thickness and the second thickness such as shown in FIG. 10B. FIG. 10B shows a heat map style plot 1001 indicating the relationship between Qa and the first thickness of the first layers 941 and the second thickness of the second layers 942 for the SM-XBAR 900A or 900B. The SM-XBAR 900A or 900B has the pitch-to-thickness ratio of 6 and a number of layers in the acoustic Bragg reflector 940 is 5.

In an example, the first materials are the high impedance materials, and the first thickness of the first layers 941 is indicated as HiZ in a unit of M, for example, from 0.2λ₁ to 0.4λ₁. λ₁ may be equal to v₁/fa which is a ratio of a first speed v₁ over the anti-resonant frequency fa. The first speed is a speed of the shear wave in the first layers. The second thickness of the second layers 942 is indicated as LoZ in a unit of λ₂, for example, from 0.2λ₂ to 0.36λ₂. λ₂ may be equal to v₂/fa which is a ratio of a second speed v₂ over the anti-resonant frequency fa. The second speed v₂ is a speed of the shear wave in the second layers. FIG. 10B indicates that Qa within a thickness range 1010 may be larger than the Qa corresponding to the first thickness being 0.25λ₁ and the second thickness being 0.25λ₂ (which is indicted by a location 1012 in the plot 1001). FIG. 10B indicates that the maxima of Qa may be obtained when the first thickness of the first layers 941 is 0.290λ₁ and the second thickness of the second layers 942 is 0.259λ₂. The maxima of Qa is a center 1011 of the thickness range 1010, and the first thickness and the second thickness at the center of the thickness range 1010 are larger than 0.25λ₁ and 0.25λ₂, respectively.

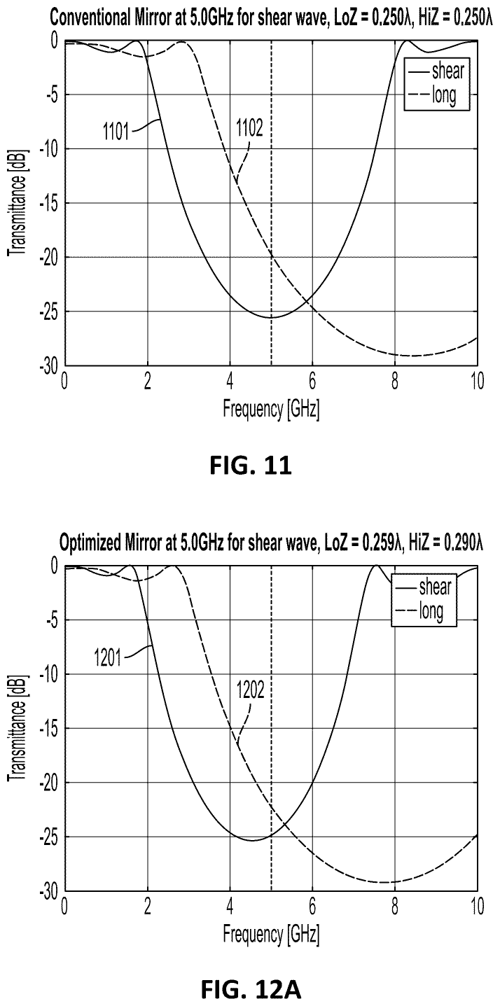

The transmissivity of each acoustic Bragg reflector (e.g., the acoustic Bragg reflector 940 with optimal thicknesses or the acoustic Bragg reflector 640) may be plotted for both the shear wave and the longitudinal wave and indicates how much a particular wave (e.g., the shear wave or the longitudinal wave) may transmit acoustic energy through the acoustic Bragg reflector into the substrate 620, such as in FIGS. 11-12.

FIG. 11 shows plots 1101-1102 indicating transmittance in unit of dB of the acoustic Bragg reflector 640 versus the frequency from 0 to 10 GHz according to an aspect of the disclosure. The plot 1101 shows the transmittance of the shear wave through the acoustic Bragg reflector 640 into the substrate 620. The plot 1102 shows the transmittance of the longitudinal wave through the acoustic Bragg reflector 640 into the substrate 620. Each first thickness of the first layers 641 is 0.25λ₁ and each second thickness of the second layers 642 is 0.25λ₂ where λ₁ and λ₂ are determined at 5 GHz. At 5 GHz, FIG. 11 shows that the transmittance (e.g., −25.5 dB) of the shear wave is relatively small as compared to the transmittance (e.g., −19.6 dB) of the longitudinal wave. Thus, in the example shown in FIG. 11, at 5 GHz, the performance of the acoustic Bragg reflector 640 for the shear wave may be optimal, however, the performance of the acoustic Bragg reflector 640 for the longitudinal wave may be suboptimal.

FIG. 12A shows plots 1201-1202 indicating transmittance in unit of dB of the acoustic Bragg reflector 940 versus the frequency from 0 to 10 GHz according to an aspect of the disclosure. The plot 1201 shows the transmittance of the shear wave through the acoustic Bragg reflector 940 into the substrate 620. The plot 1202 shows the transmittance of the longitudinal wave through the acoustic Bragg reflector 940 into the substrate 620. Each first thickness of the first layers 641 is 0.290λ₁ and each second thickness of the second layers 642 is 0.259λ₂ where λ₁ and λ₂ are determined at about 5 GHz. At about 5 GHz, FIG. 12A illustrates that both the transmittance (e.g., −24.9 dB) of the shear wave and the transmittance (e.g., −22.3 dB) of the longitudinal wave are relatively small. Thus, in the example shown in FIG. 12A, the performance of the acoustic Bragg reflector 940 for both the shear wave and the longitudinal wave may be optimal. FIG. 12A shows that the transmittance for the longitudinal wave is greatly improved (e.g., by 2.7 dB from −19.6 dB to −22.3 dB) at only a small increase in transmittance of the shear wave (e.g., by 0.6 dB from −25.5 dB to −24.9 dB).

FIG. 12B shows plots indicating transmittance in unit of dB of the acoustic Bragg reflector 940A versus the frequency from 5.5 to 7.5 GHz according to an exemplary aspect of the disclosure. The long-dashed plot shows the transmittance of the shear wave through the acoustic Bragg reflector 940A into the substrate 620. The solid line plot shows the transmittance of the longitudinal wave through the acoustic Bragg reflector 940A into the substrate 620. Each first thickness of the first layers 641 is 0.250λ₁ and each second thickness of the second layers 642 is also 0.250λ₂ where λ₁ and λ₂ are determined at about 6.5 GHZ. At about 6.5 GHZ, FIG. 12B illustrates that both the transmittance (e.g., −28.2 dB) of the shear wave and the transmittance (e.g., −19.5 dB) of the longitudinal wave are relatively small. Thus, in the example shown in FIG. 12B, the performance of the acoustic Bragg reflector 940A for both the shear wave and the longitudinal wave may be significant improved compared with an exemplary resonator, such as that shown in FIG. 6.

FIGS. 10A-10B, 11, and 12A-B indicate that when the first thickness and/or the second thickness are optimized, the transmittance of the longitudinal wave is greatly improved (e.g., reduced by 2.7 dB) at only a small increase (e.g., by 0.6 dB) in transmittance of the shear wave, and the Q factor of the SM-XBAR using the improved acoustic Bragg reflector 940 may be increased, such as shown in Table 2.

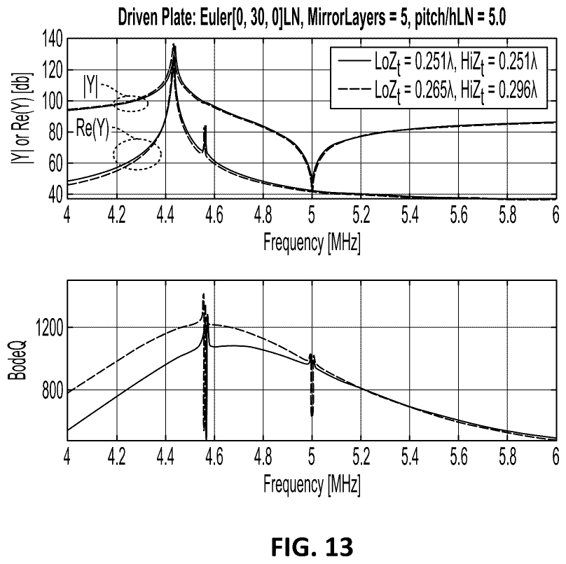

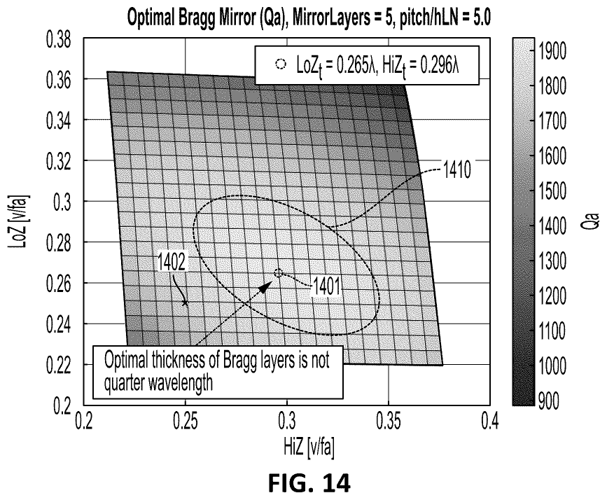

FIGS. 10A-10B show an example where the SM-XBAR 900A or 900B is improved where the pitch-to-thickness ratio is 6. FIGS. 13-14 show another example where the SM-XBAR 900A or 900B is improved, and the pitch-to-thickness ratio is 5. FIG. 13 compares performances of an example of the SM-XBAR 600 and an example of the SM-XBAR 900A or 900B according to an aspect of the disclosure. For each of the SM-XBAR 600 and the SM-XBAR 900A (or 900B), the pitch-to-thickness ratio is 5, and the piezoelectric layer 610 has Euler angles [0°, 30°, 0°] and is referred to as “120Y.” A number of layers in each of the acoustic Bragg reflector 640 and the acoustic Bragg reflector 940 is 5.

In the example of the SM-XBAR 600, each first thickness of the first layers 641 is 0.25λ₁ and each second thickness of the second layers 642 is 0.25λ₂ as shown in FIG. 6. In the example of the SM-XBAR 900A or 900B, each first thickness of the first layers 941 is 0.296λ₁ and each second thickness of the second layers 942 is 0.265λ₂.

Referring to FIG. 13, the top graphs show admittance curves (Y-parameters) of the SM-XBAR 600 and the SM-XBAR 900A (or 900B) versus a frequency in unit of GHz according to some examples of the disclosure. The frequency range is from 4 to 6 GHz. Both IYI and Re(Y) of the Y-parameters are plotted. The Y-parameters in FIG. 13 indicate that the SM-XBAR 900A (or 900B) and the SM-XBAR 600 have a resonance frequency at approximately 4.44 GHz, and an anti-resonance frequency at approximately 5 GHz.

The bottom graphs in FIG. 13 show BodeQ plots versus the frequency. The BodeQ plot in long dashes corresponds to the SM-XBAR 900A or 900B and the BodeQ plot in solid line corresponds to the SM-XBAR 600. The BodeQ plots indicate that Q factors of the SM-XBAR 900A or 900B are higher than Q factors of the SM-XBAR 600 at the resonance frequency and the anti-resonance frequency, respectively. The BodeQ plots indicate that the SM-XBAR 900A or 900B with the improved thicknesses are more efficient than the SM-XBAR 600.

To determine an optimal pair of the first thickness of the first layers 941 and the second thickness of the second layers 942, Qa is determined (e.g., calculated) at the anti-resonant frequency for various combinations of the first thickness and the second thickness as shown in FIG. 14. FIG. 14 shows a heat map style plot indicating the relationship between Qa and the first thickness of the first layers 941 and the second thickness of the second layers 942 for the SM-XBAR 900A or 900B. The SM-XBAR 900A or 900B has the pitch-to-thickness ratio of 5 and a number of layers in the acoustic Bragg reflector 940 is 5.

In an example, the first materials are the high impedance materials, and the first thickness of the first layers 941 is indicated as HiZ in a unit of M, for example, from 0.2λ₁ to 0.4λ₁. The second thickness of the second layers 942 is indicated as LoZ in a unit of λ₂, for example, from 0.2λ₂ to 0.38λ₂. λ₁ and λ₂ are described in FIG. 10B and may be determined at the anti-resonant frequency. FIG. 14 indicates that Qa within a thickness range 1410 may be larger than the Qa (at a location 1402) corresponding to the first thickness being 0.25λ₁ and the second thickness being 0.25λ₂. FIG. 14 indicates that the maxima of Qa may be obtained when the first thickness of the first layers 941 is 0.296λ₁ and the second thickness of the second layers 942 is 0.265λ₂. The maxima of Qa is a center 1401 of the thickness range 1410, and the first thickness and the second thickness at the center of the thickness range 1410 are larger than 0.25λ₁ and 0.25λ₂, respectively.

Referring to FIGS. 10A-10B, 13, and 14, in some examples, the optimal first thickness of each first layer may not be λ₁/4 and the optical second thickness of each second layer in the acoustic Bragg reflector 940 may not be λ₂/4. In some examples, the optimal first thickness of each first layer may be larger than λ₁/4 and the optical second thickness of each second layer in the acoustic Bragg reflector 940 may be larger than λ₂/4.

An optimal thickness range such as the thickness range 1010 or the thickness range 1410 where a Q factor of the SM-XBAR is relatively large may depend on various factors, such as materials used in the acoustic Bragg reflector 940 (e.g., the first materials and the second materials), a number of layers in the acoustic Bragg reflector 940, the frequency (e.g., the anti-resonant frequency, the resonant frequency, or a frequency between the resonant frequency and the anti-resonant frequency) where the optimal thickness range is determined, and/or the like. Material properties of the first materials and the second materials used in the acoustic Bragg reflector 940 may include respective material Q factors of the first materials and the second materials. A Q factor of a material (also referred to as a material Q factor) such as a Q factor of the first materials Q_{Hiz} or a Q factor of the second materials Q_{LoZ} may indicate how lossy the material is with respect to the acoustic energy. In an example, the material Q factor may decrease with an increase of the viscosity of the material. The material may become more lossy when the material Q factor decreases. In an example, the optimal thickness range may depend on impedances of the first materials and the second materials, such as an impedance ratio of the first impedance of the first materials over the second impedance of the second materials.

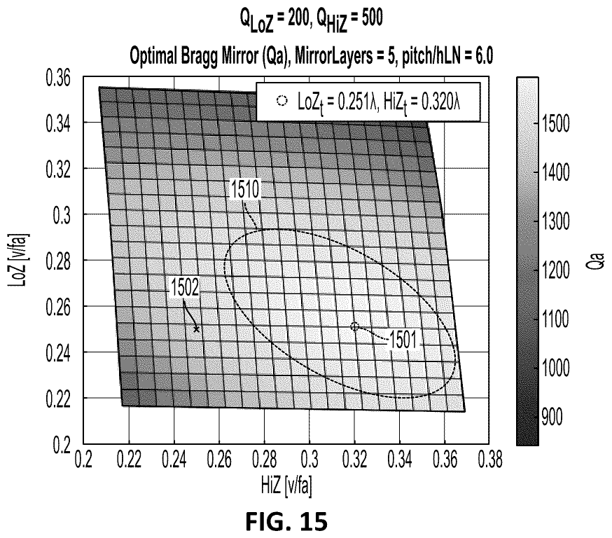

FIGS. 15-17 show an effect of material properties such as material attenuation on the optimization of the first thickness and the second thickness in the acoustic Bragg reflector 940 according to an aspect of the disclosure. For example, the optimal layer thicknesses may vary based on the material attenuation of HiZ materials (e.g., the first materials) and LoZ materials (e.g., the second materials). In an example, the first materials are the high impedance materials, and the first thickness of the first layers 941 is indicated as HiZ in a unit of λ₁. The second thickness of the second layers 942 is indicated as LoZ in a unit of λ₂. For the SM-XBAR 900A including the acoustic Bragg reflector 940 in FIGS. 15-17, the pitch-to-thickness ratio is 6, and the number of layers in the acoustic Bragg reflector 940 is 5.

Referring to FIG. 15, a Q factor of the first materials Q_{HiZ} and a Q factor of the second materials Q_{LoZ} are 500 and 200, respectively. A center 1501 of a thickness range 1510 corresponds to the first thickness being 0.320λ₁ and the second thickness being 0.251λ₂.

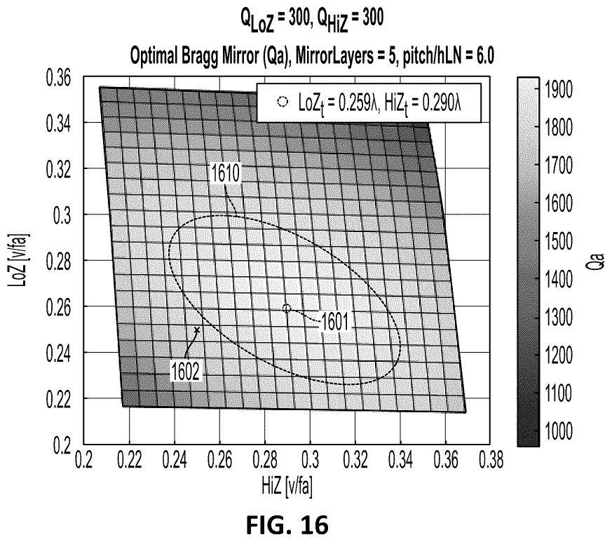

Referring to FIG. 16, Q_{HiZ} is 300 and Q_{LoZ} is 300. A center 1601 of a thickness range 1610 corresponds to the first thickness being 0.290λ₁ and the second thickness being 0.259λ₂.

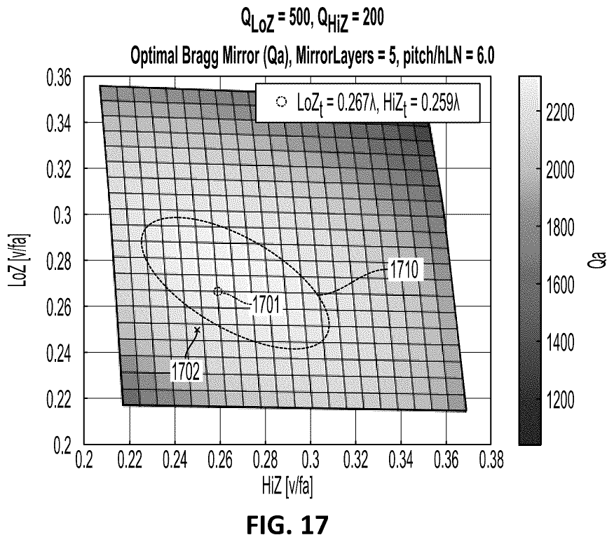

Referring to FIG. 17, Q_{HiZ} is 200 and Q_{LoZ} is 500. A center 1701 of a thickness range 1710 corresponds to the first thickness being 0.259λ₁ and the second thickness being 0.267λ₂.

Comparing FIGS. 15-17, the centers 1501, 1601, and 1701 move toward the respective locations 1502, 1602, and 1702, when the Q factor of the second materials increases and the Q factor of the first materials decreases. The locations 1502, 1602, and 1702 correspond to the first thickness being 0.25λ₁ and the second thickness being 0.25λ₂ of the SM-XBAR 600. Thus, when the Q factor of the second materials decreases and the Q factor of the first materials increases, the optimal pair of the first thickness and the second thickness is farther away from the pair of the first thickness and the second thickness in the acoustic Bragg reflector 640.

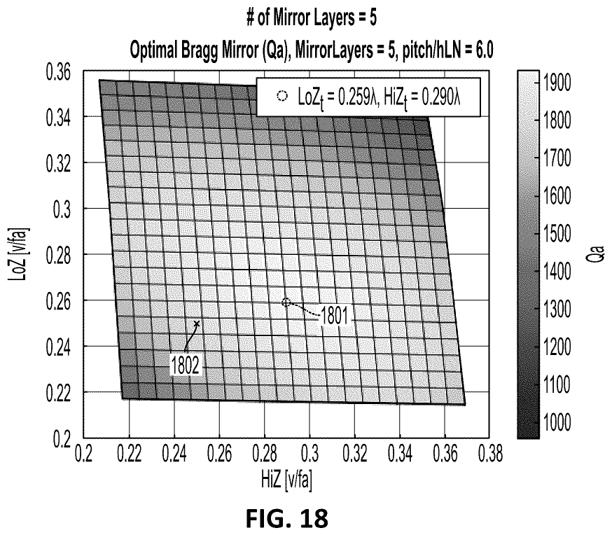

FIGS. 18-20 show an effect of the number of layers in the acoustic Bragg reflector 940 according to an aspect of the disclosure. For the SM-XBAR 900A or 900B including the acoustic Bragg reflector 940 in FIGS. 18-20, the pitch-to-thickness ratio is 6, and the number of layers in the acoustic Bragg reflector 940 vary from 5 to 7, respectively. In an example, the first materials are the high impedance materials, and the first thickness of the first layers 941 is indicated as HiZ in a unit of M. The second thickness of the second layers 942 is indicated as LoZ in a unit of λ₂.

Referring to FIG. 18, the number of layers in the acoustic Bragg reflector 940 is 5. A center 1801 having the maximal Qa corresponds to the first thickness being 0.290λ₁ and the second thickness being 0.259λ₂.

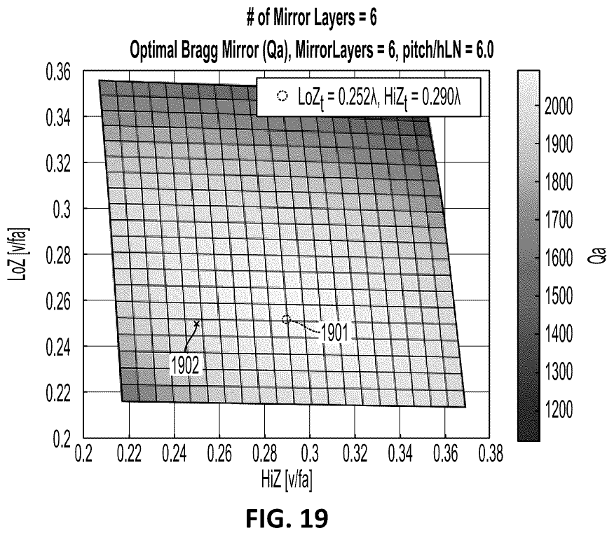

Referring to FIG. 19, the number of layers in the acoustic Bragg reflector 940 is 6. A center 1901 having the maximal Qa corresponds to the first thickness being 0.290λ₁ and the second thickness being 0.252λ₂.

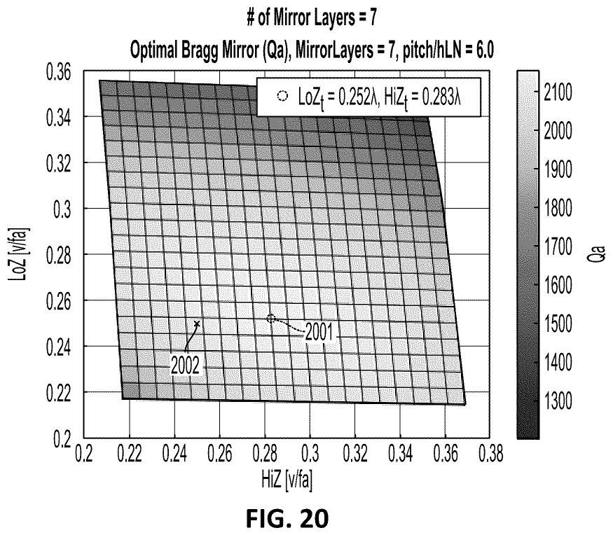

Referring to FIG. 20, the number of layers in the acoustic Bragg reflector 940 is 7. A center 2001 having the maximal Qa corresponds to the first thickness being 0.283λ₁ and the second thickness being 0.252λ₂.

Comparing FIGS. 18-20, the number of layers does not significantly change the optimal layer thicknesses. For example, a difference between the first thicknesses of the centers 1801 and 1901 is 0 and a difference between the second thicknesses of the centers 1801 and 1901 is 0.007λ₂. Distances between the centers 1801, 1901, and 2001 and the respective locations 1802, 1902, and 2002 are similar. The locations 1802, 1902, and 2002 correspond to the first thickness being 0.25λ₁ and the second thickness being 0.25λ₂ of the SM-XBAR 600 including the acoustic Bragg reflector 640.

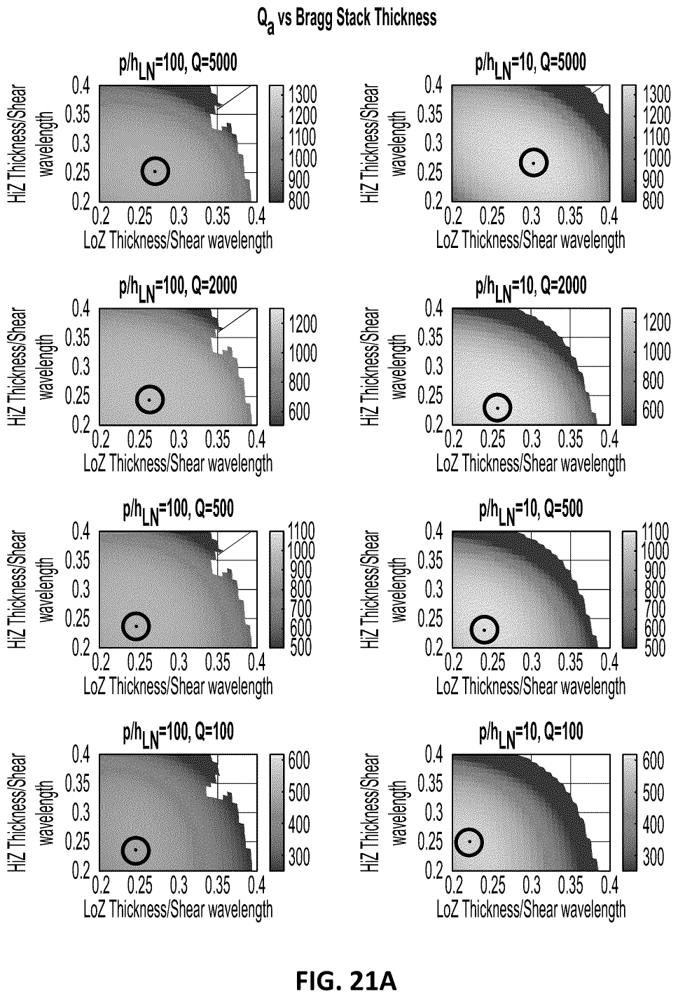

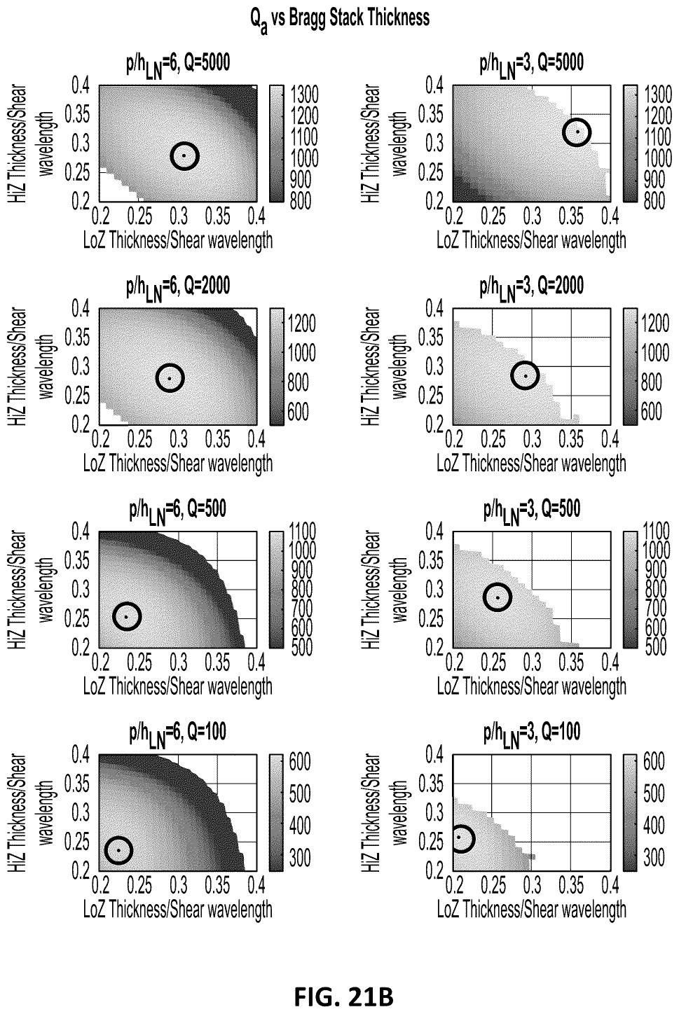

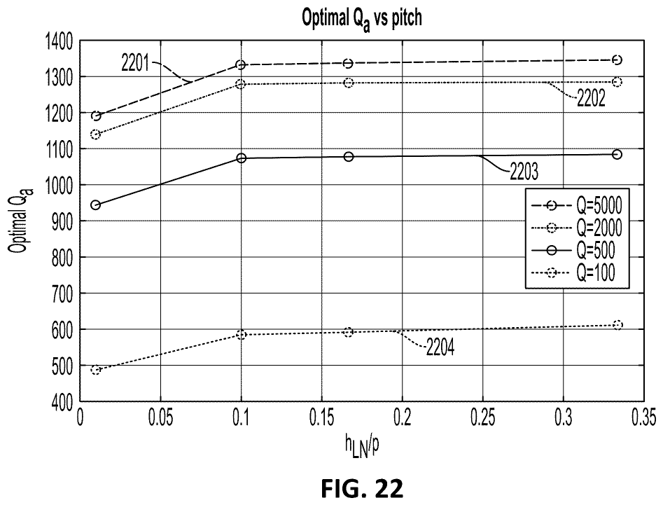

FIGS. 21A, 21B and 22 show effects of material properties (indicated by the Q factors of the first materials and the second materials) and the pitch-to-thickness ratio on the optimization of the first thickness and the second thickness in the acoustic Bragg reflector 940 according to an aspect of the disclosure. In an example, the first materials are the high impedance materials, and the first thickness of the first layers 941 is indicated as HiZ in a unit of λ₁. The second thickness of the second layers 942 is indicated as LoZ in a unit of λ₂.

Referring to FIGS. 21A and 21B, the first, second, third, and fourth rows in each figure correspond to the Q factors of the first materials and the second materials being 5000, 2000, 500, and 100 respectively. Thus, the first materials and the second materials are more lossy from the first row to the fourth row. Within each row, each 2D heat map is associated with a respective pitch-to-thickness ratio and indicates the relationship between Qa and the first thickness of the first layers 941 and the second thickness of the second layers 942 for the SM-XBAR 900A or 900B. Within each row, the pitch-to-thickness ratios corresponding to the first, second, third, and fourth columns are 100, 10, 6, and 3, respectively.

As further shown in FIGS. 21A and 21B, each circle indicates an optimal pair of the first thickness and the second thickness for a corresponding combination of the Q factor of the first materials and the second materials and the pitch-to-thickness ratio. It is noted that a position of the indicated circle may vary with the combination of the Q factor of the first materials and the second materials and the pitch-to-thickness ratio, and thus the optimal pair of the first thickness and the second thickness may depend on the Q factor of the first materials and the second materials and the pitch-to-thickness ratio. Accordingly, the first thickness and the second thickness may be determined (e.g., improved) when different materials are used for the acoustic Bragg reflector 940 and/or different pitch-to-thickness ratio are used for the SM-XBAR 900A or 900B.

In an example, for each row in the top three rows, the optimal pairs of the first thickness and the second thickness corresponding to the maxima of Qa (indicated by the circles) shift from relatively small first and second thicknesses for the relatively large pitch-to-thickness ratios (e.g., 100 and 10 in the first and second columns) toward a larger first thickness and a larger second thickness for the relatively small pitch-to-thickness ratios (e.g., 6 and 3 in the third and fourth columns).

FIGS. 21A and 21B also illustrate that when the pitch-to-thickness ratio is relatively large (e.g., 100), the improved first thickness may be less than 0.25λ₁ (e.g., 0.23λ₁) and/or the improved second thickness may be less than 0.25λ₂. In an example, the second thickness of at least one of the second layers is from 0.21λ₂ to less than 0.25λ₂. In an example, the first thickness of at least one of the first layers is from 0.23λ₁ to less than 0.25λ₁.

Referring to FIGS. 21A and 21B, in an example, when the pitch-to-thickness ratio is 3 and the Q factors of the first materials and the second materials are 100, the improved second thickness may be approximately 0.21λ₂. In an example, when the pitch-to-thickness ratio is 6 and the Q factors of the first materials and the second materials are 100, the improved first thickness may be approximately 0.23λ₁, and the improved second thickness may be approximately 0.22λ₂. In an example, when the pitch-to-thickness ratio is 10 and the Q factors of the first materials and the second materials are 100, the improved first thickness may be approximately 0.25λ₁, and the improved second thickness may be approximately 0.22λ₂. In an example, when the pitch-to-thickness ratio is 100 and the Q factors of the first materials and the second materials are 100, the improved first thickness may be approximately 0.24λ₁, and the improved second thickness may be approximately 0.25λ₂.

In an example, when the pitch-to-thickness ratio is 100 and the Q factors of the first materials and the second materials are 500, the improved first thickness may be approximately 0.24λ₁, and the improved second thickness may be approximately 0.25λ₂. In an example, when the pitch-to-thickness ratio is 10 and the Q factors of the first materials and the second materials are 500, the improved first thickness may be approximately 0.23λ₁, and the improved second thickness may be approximately 0.24λ₂. In an example, when the pitch-to-thickness ratio is 6 and the Q factors of the first materials and the second materials are 500, the improved first thickness may be approximately 0.25λ₁, and the improved second thickness may be approximately 0.23λ₂.

In an example, when the pitch-to-thickness ratio is 10 and the Q factors of the first materials and the second materials are 2000, the improved first thickness may be approximately 0.23λ₁, and the improved second thickness may be approximately 0.25λ₂.

FIG. 22 shows the maximal Qa (e.g., optimal Qa) versus an inverse of the pitch-to-thickness ratio according to an aspect of the disclosure. The maximal Qa in FIG. 22 is obtained from FIGS. 21A and 21B. Referring to FIG. 22, curves 2201-2204 correspond to the Q factors of the first materials and the second materials being 5000, 2000, 500, and 100 respectively. For each curve, the maximal Qa increases as the pitch-to-thickness ratio decreases. For example, the curve 2201 (the Q factor being 5000) indicates that the maxima Qa increases from approximately 1200 at the pitch-to-thickness ratio of 100 and reaches a plateau of approximately 1340 around the pitch-to-thickness ratio of 10. Thus, using a relatively small pitch-to-thickness ratio (e.g., less than 10) may be advantageous as the maximal Qa for the relatively small pitch-to-thickness ratio (e.g., less than 10) may be larger than the maximal Qa for the relatively large pitch-to-thickness ratio (e.g., larger than 10).

FIG. 22 also indicates that the maxima Qa increases with the Q factors of the first materials and the second materials. For example, when the pitch-to-thickness ratio is 6, the maxima Qa increases from approximately 600 (the Q factor being 100) to approximately 1340 (the Q factor being 5000).

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator, comprising:
a piezoelectric layer;
an interdigital transducer (IDT) including a plurality of interleaved fingers on the piezoelectric layer;
a substrate, and
an acoustic reflector between the piezoelectric layer and the substrate including alternating first layers of first materials and second layers of second materials that are different than the first materials,
wherein a ratio of a pitch of the IDT over a thickness of the piezoelectric layer is less than 10, a first thickness of the at least one first layer is larger than a quarter of a first wavelength λ₁, wherein λ₁ is an acoustic wavelength of a shear bulk wave in the at least one first layer at a resonance frequency of the SM-XBAR.

2. The acoustic resonator of claim 1, wherein the first thickness of the at least one first layer is between 0.26λ₁ to 0.32λ₁.

3. The acoustic resonator of claim 1, wherein a second thickness of the at least one second layer is larger than a quarter of a second wavelength λ₂, and λ₂ is an acoustic wavelength of the shear bulk wave in the at least one second layer.

4. The acoustic resonator of claim 3, wherein the second thickness of the at least one second layer is between 0.26λ₂ to 0.32λ₂.

5. The acoustic resonator of claim 4, wherein the first thickness of the at least one first layer is between 0.26λ₁ to 0.32λ₁.

6. The acoustic resonator of claim 1, wherein a first acoustic impedance of the first material of at least one first layer of the first layers is larger than a second acoustic impedance of the second material of at least one second layer of the second layers.

7. The acoustic resonator of claim 6, wherein the first thickness of the at least one first layer is less than 0.35λ₁.

8. The acoustic resonator of claim 7, wherein a second thickness of at least one second layer is between 0.21λ₂ to less than 0.25λ₂, and λ₂ is an acoustic wavelength of the shear bulk wave in the at least one second layer.

9. The acoustic resonator of claim 1, wherein the piezoelectric layer and the IDT are configured such that a radio frequency signal applied to the IDT excites a primary shear acoustic mode in the piezoelectric layer, such that an electric field is excited in a substantially lateral direction in the piezoelectric layer, and wave propagation of the primary shear acoustic mode is substantially perpendicular to the lateral direction of the electric field.

10. The acoustic resonator of claim 1, wherein:
the plurality of interleaved fingers includes first parallel fingers extending from a first busbar and second parallel fingers extending from a second busbar, the first and second parallel fingers are interleaved with each other, and the first busbar and the second busbar are disposed on the piezoelectric layer, and
the IDT is on a surface of the piezoelectric layer and the thickness of the piezoelectric layer and the first thickness are measured in a direction orthogonal to the surface of the piezoelectric layer.

11. The acoustic resonator of claim 1, wherein a thickness of at least one additional layer of the first layers of the first materials is greater than 0.75λ₁ or a thickness of at least one additional layer of the second layers of second materials is greater than 0.75λ₂.

12. The acoustic resonator of claim 1, wherein the IDT and the acoustic reflector are on a same side of the piezoelectric layer.

13. The acoustic resonator of claim 1, wherein the IDT and the acoustic reflector are on different sides of the piezoelectric layer.

14. A bandpass filter, comprising:
a plurality of acoustic resonators comprising one or more series resonators and one or more shunt resonators, one of the plurality of acoustic resonators including a solidly-mounted transversely-excited bulk acoustic resonator (SM-XBAR) that includes:
a piezoelectric layer,
an interdigital transducer (IDT) including a plurality of interleaved fingers on the piezoelectric layer,
a substrate, and
an acoustic reflector between the piezoelectric layer and the substrate, the acoustic reflector being on the piezoelectric layer, the acoustic reflector includes alternating first layers of first materials and second layers of second materials that are different than the first materials,
wherein a ratio of a pitch of the IDT over a thickness of the piezoelectric layer is less than 10, a first thickness of at least one of the first layers is larger than a quarter of a first wavelength λ₁, and
wherein λ₁ is an acoustic wavelength of a shear bulk wave in the at least one of the first layers at a resonance frequency of the SM-XBAR.

15. The bandpass filter of claim 14, wherein the first thickness of the at least one of the first layers is between 0.26λ₁ to 0.32λ₁.

16. The bandpass filter of claim 14, wherein a second thickness of at least one of the second layers is larger than a quarter of a second wavelength λ₂, and λ₂ is an acoustic wavelength of the shear bulk wave in the at least one of the second layers.

17. The bandpass filter of claim 16, wherein the second thickness of the at least one of the second layers is between 0.26λ₂ to 0.32λ₂.

18. The bandpass filter of claim 17, wherein the first thickness of the at least one of the first layers is between 0.26λ₁ to 0.32λ₁.

19. The bandpass filter of claim 14, wherein a first acoustic impedance of the first materials is larger than a second acoustic impedance of the second materials.

20. The bandpass filter of claim 19, wherein the first thickness of the at least one of the first layers is less than 0.35λ₁.
